(19) United States
(12) Patent Application Publication
(10) Pub. No.: US 2026/0150663 A1
(43) Pub. Date: May 28, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Yu-Cheng TSAI, Tainan City (TW); Meng-Hsien LIN, Tainan City (TW); Hsing-Chih LIN, Tainan City (TW); Jen-Cheng LIU, Hsin-Chu City (TW); Ko Chun LIU, Toufen (TW); Jaio-Wei WANG, Kaohsiung City (TW)

(21) Appl. No.: 18/961,917

(22) Filed: Nov. 27, 2024

(51) Int. Cl. H01L 23/522

(52) U.S. Cl. CPC H10W 20/496

(57) ABSTRACT

A capacitor structure (e.g., a trench capacitor structure) is formed in an interconnect layer of a semiconductor device. Instead of etching the dielectric layers of the interconnect layer to form the trenches (e.g., the deep trenches) for the capacitor structure, a wide main trench (e.g., having a relatively low aspect ratio) is formed in the dielectric layers of the interconnect layer. The main trench is filled with a dielectric plug, and the dielectric plug is patterned and used to form a plurality of columns of a bottom electrode structure of the capacitor structure. The columns of the bottom electrode structure define a plurality of secondary trenches (e.g., that have a relatively high aspect ratio) in the main trench that are then lined with an insulator layer of the capacitor structure and filled in with a plurality of columns of a top electrode structure of the capacitor structure.

### BACKGROUND

A semiconductor device may include one or more capacitor structures in an interconnect layer (e.g., a back end of line (BEOL) region or back end region) above a device layer. A capacitor structure may perform and/or support one or more functions in the semiconductor device, such as memory (e.g., dynamic random access memory (DRAM)), charge decoupling, analog-to-digital (A/D) conversion, and/or other functions. In some cases, a capacitor structure may be included in a pixel sensor circuit of an image sensor device to provide for overflow photocurrent storage to achieve increased full well capacity for the pixel sensor circuit.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example implementation of a semiconductor device described herein.

FIGS. 2A and 2B are diagrams of an example implementation of a capacitor structure described herein.

FIGS. 3A-3F are diagrams of an example implementation of forming a semiconductor device described herein.

FIGS. 4A-4L are diagrams of an example implementation of forming a capacitor structure described herein.

FIG. 5 is a flowchart of an example process associated with forming a capacitor structure in a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A capacitor structure may include a metal-insulator-metal (MIM) structure in which an insulator layer is sandwiched between two conductive electrode layers. The capacitance of the capacitor structure (e.g., the amount of charge that can be stored by the capacitor structure) is directly dependent on the geometry of the conductive electrode layers of the capacitor structure. The greater the surface area of the conductive electrode layers, the greater the capacitance of the capacitor structure. Thus, increasing the size of the metal electrode layers may increase the capacitance of the capacitor structure.

Increasing a lateral size of the capacitor structure is in direct contention with semiconductor design principles in the semiconductor industry, in which reducing semiconductor device sizes is pursued in order to achieve reduced power consumption, to achieve greater operating performance and efficiencies, and/or to enable semiconductor devices to be used in increasingly smaller form factor applications. Thus, in some cases, the size of a capacitor structure may be increased in a vertical direction in a semiconductor device such that the capacitor structure extends through a plurality of layers in the semiconductor device. A deep trench capacitor (DTC) is a type of capacitor structure that is formed in a deep trench in a semiconductor device such that the electrode layers and insulator layer extend along, and conform to, a profile of the deep trench. This enables the area of the conductive electrode layers to be increased (which increases the capacitance) with minimal increase in the lateral size of the capacitor structure.

However, forming the deep trenches for a DTC by etching can be challenging in that achieving a high aspect ratio for the deep trenches (e.g., a high ratio of a depth to a width of the deep trenches) can be difficult due to lateral etching. Moreover, the deeper the deep trenches, the higher the likelihood that the sidewalls of the deep trenches will collapse. These challenges can result in failure and reduced yield of DTCs formed in a semiconductor device.

In some implementations described herein, a capacitor structure (e.g., a trench capacitor structure or DTC structure) is formed in an interconnect layer of a semiconductor device. Instead of etching the dielectric layers of the interconnect layer to form the trenches (e.g., the deep trenches) for the capacitor structure, a wide main trench (e.g., having a relatively low aspect ratio) is formed in the dielectric layers of the interconnect layer. The main trench is filled with a dielectric plug, and the dielectric plug is patterned and used to form a plurality of columns (or “fingers”) of a bottom electrode structure of the capacitor structure. The columns of the bottom electrode structure define a plurality of secondary trenches in the main trench that are then lined with an insulator layer of the capacitor structure and filled in with a plurality of columns (or “fingers”) of a top electrode structure of the capacitor structure.

The secondary trenches are therefore formed of metal (e.g., corresponding to the material of columns of the bottom electrode structure), which is less prone to collapse compared to a case where the secondary trenches were formed of the dielectric material of the dielectric layers of the interconnect layer. This reduces the likelihood of failure of the capacitor structure and increases the yield of capacitor structures formed in the semiconductor device.

Moreover, using the columns of the bottom electrode structure to define the secondary trenches in which the insulator layer and columns of the top electrode structure are formed increases the utilization of the volume within the main trench for the MIM stack of the capacitor structure (e.g., where the dielectric material of the dielectric layers of the interconnect layer to define the secondary trenches takes away area in the main trench from the MIM stack of the capacitor structure). This increases the capacitance of the capacitor structure.

In addition, the main trench may be lined with a liner (e.g., a barrier liner, an adhesion liner) that may also function as an etch stop liner when patterning the dielectric plug. This reduces the likelihood of lateral etching into the dielectric layers of the interconnect layer (e.g., compared to using the dielectric layers of the interconnect layer to define the secondary trenches), which enables a high aspect ratio to be achieved for the secondary trenches.

In this way, a capacitor structure (e.g., a trench capacitor structure or DTC structure) is formed in an interconnect layer of a semiconductor device. Instead of etching the dielectric layers of the interconnect layer to form the trenches (e.g., the deep trenches) for the capacitor structure, a wide main trench (e.g., having a relatively low aspect ratio) is formed in the dielectric layers of the interconnect layer. The main trench is filled with a dielectric plug, and the dielectric plug is patterned and used to form a plurality of columns of a bottom electrode structure of the capacitor structure. The columns of the bottom electrode structure define a plurality of secondary trenches in the main trench that are then lined with an insulator layer of the capacitor structure and filled in with a plurality of columns of a top electrode structure of the capacitor structure.

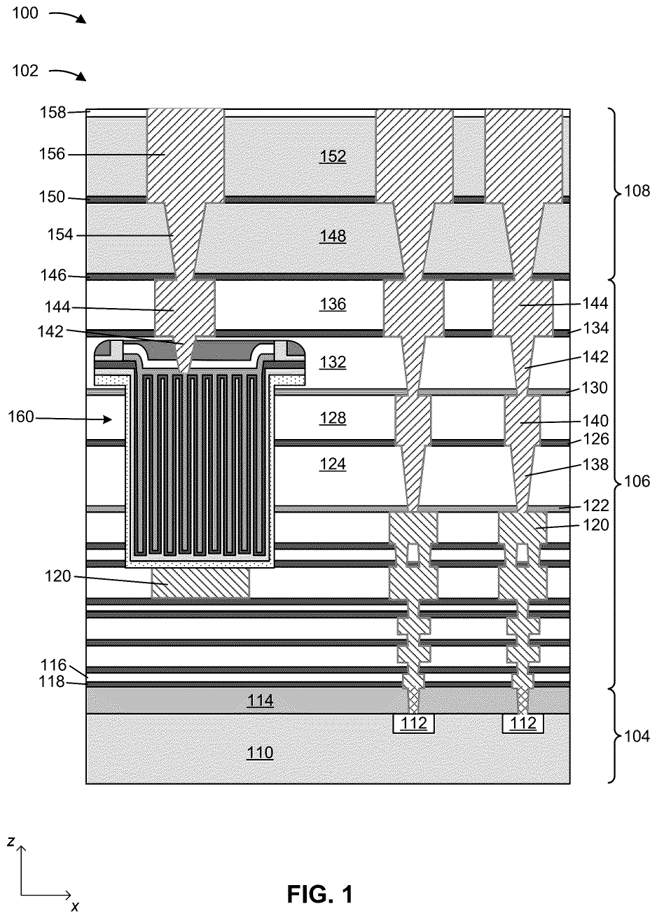

FIG. 1 is a diagram of an example implementation 100 of a semiconductor device 102 described herein. The semiconductor device 102 may include a system on chip (SoC) die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the semiconductor device 102 may include a memory die, an input/output (I/O) die, a pixel sensor die, and/or another type of semiconductor die. A memory die may include a static random access memory (SRAM) die, a DRAM die, a NAND die, a high bandwidth memory (HBM) die, and/or another type of memory die. In general, the semiconductor device 102 is a semiconductor device that includes one or more capacitor structures in an interconnect layer of the semiconductor device 102.

As shown in FIG. 1, the semiconductor device 102 includes a device layer 104, an interconnect layer 106 vertically arranged (e.g., in a z-direction) in the semiconductor device 102 with the device layer 104, and a bonding layer 108 vertically arranged (e.g., in a z-direction) in the semiconductor device 102 with the interconnect layer 106.

The device layer 104 may also be referred to as a frontend region or a front end of line (FEOL) region of the semiconductor device 102. The device layer 104 includes a substrate layer 110. The substrate layer 110 may correspond to a portion of a semiconductor wafer on which the semiconductor device 102 is formed. The substrate layer 110 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate layer 110 may extend in an x-direction and/or in a y-direction in the semiconductor device 102.

Integrated circuit devices 112 may be included in and/or on the substrate layer 110 in the device layer 104 of the semiconductor device 102. The integrated circuit devices 112 may include frontend transistor structures (e.g., frontend planar transistor structures, frontend fin field effect transistor (finFET) structures, frontend gate all around (GAA) transistor structures), pixel sensors, frontend capacitors, frontend resistors, frontend inductors, photodetectors, transceivers, transmitters, receivers, optical circuits, and/or other types of frontend semiconductor devices. “Frontend semiconductor devices” refers to the semiconductor devices that are formed in the device layer 104 (e.g., in and/or on the substrate layer 110) of the semiconductor device 102, as opposed to in the interconnect layer 106 of the semiconductor device 102.

A dielectric layer 114 is included over the substrate layer 110. The dielectric layer 114 includes an interlayer dielectric (ILD) layer, an etch stop layer (ESL), and/or another type of dielectric layer. The dielectric layer 114 includes dielectric material(s) that enable various portions of the substrate layer 110 and/or the integrated circuit devices 112 to be selectively etched or protected from etching, and/or to electrically isolate the integrated circuit devices 112 in the device layer 104. The dielectric layer 114 includes a silicon nitride (SiₓN_{y}), an oxide (e.g., a silicon oxide (SiOₓ) and/or another oxide material), and/or another type of dielectric material. The dielectric layer 114 may extend in the x-direction and/or in a y-direction in the semiconductor device 102.

The interconnect layer 106 of the semiconductor device 102 is included above the substrate layer 110 and above the integrated circuit devices 112 in the z-direction in the semiconductor device 102. The integrated circuit devices 112 may be electrically coupled to the interconnect layer 106. The interconnect layer 106 includes a plurality of dielectric layers (e.g., backend dielectric layers) that are arranged in a direction (e.g., the z-direction) that is approximately perpendicular to the substrate layer 110. The dielectric layers may include ILD layers 116 and ESLs 118 that are arranged in an alternating manner in the z-direction. The ILD layers 116 and the ESLs 118 may extend in the x-direction and/or in the y-direction in the semiconductor device 102.

The ILD layers 116 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 116 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (α-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 118 may each include a silicon nitride (SiₓN_{y}), silicon carbide (SiC), silicon oxynitride (SiON), and/or another suitable dielectric material. In some implementations, an ILD layer 116 and an ESL 118 include different dielectric materials to provide etch selectivity to enable various structures to be formed in the interconnect layer 106.

The interconnect layer 106 includes a plurality of conductive structures. One or more of the conductive structures 120 are electrically coupled and/or physically coupled with one or more of the integrated circuit devices 112 in the device layer 104. The conductive structures 120 provide electrical routing that enables signals and/or power to be provided to and/or from the integrated circuit devices 112. The conductive structures 120 may include a combination of metallization structures and interconnect structures. The metallization structures may include trenches, metallization layers, conductive traces, and/or other types of metallization structures. The interconnect structures may include vias, plugs, interconnects, and/or another type of interconnect structures. The conductive structures 120 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included on the conductive structures 120. The one or more liner layers may include barrier liners, adhesion liners, and/or another type of liners. Examples of materials for the one or more liners include tantalum nitride (TaN) and/or titanium nitride (TiN), among other examples.

In some implementations, the conductive structures 120 may be arranged in a plurality of layers that are arranged in a vertical manner (e.g., in the z-direction) in the interconnect layer 106. In other words, a plurality of layers of conductive structures 120 may extend above the device layer 104 in the interconnect layer 106 to facilitate electrical signals and/or power to be routed between the device layer 104 and the interconnect layer 106. The metallization structures may be arranged in metallization layers referred to as M-layers. For example, a metal-0 (M0) layer that includes a plurality of conductive structures 120 (e.g., metallization structures) may be located at the bottom of the interconnect layer 106 and may be directly coupled with the device layer 104 (e.g., with the integrated circuit devices 112 in the device layer 104). A via-1 (V1) layer that includes a plurality of conductive structures (e.g., interconnect structures) may be included above the M0 layer. A metal-1 layer (M1) layer that includes a plurality of conductive structures 120 (e.g., metallization structures) may be located above the V1 layer in the interconnect layer 106, a via-2 (V2) layer that includes a plurality of conductive structures (e.g., interconnect structures) may be included above the M1 layer, a metal-2 layer (M2) layer that includes a plurality of conductive structures 120 (e.g., metallization structures) may be located above the V2 layer, and so on.

One or more top metal layers may be included above the conductive structures 120 (e.g., the M-layers and the V-layers) in the interconnect layer 106. For example, the interconnect layer 106 may include an ESL 122, an ILD layer 124, an ESL 126, an ILD layer 128, an ESL 130, an ILD layer 132, an ESL 134, and an ILD layer 136, and may include a top via 138 (e.g., extending through the ESL 122 and the ILD layer 124), a top metal layer 140 (e.g., extending through the ESL 126 and the ILD layer 128), a top via 142 (e.g., extending through the ESL 130 and the ILD layer 132), and/or a top metal layer 144 (e.g., extending through the ESL 134 and/or the ILD layer 136), among other examples.

The top vias 138 and 142 may be physically larger (e.g., may be taller in the z-direction) than the interconnect structures of the conductive structures 120. Similarly, the top metal layers 140 and 144 may be physically larger (e.g., may be taller in the z-direction) than the metallization structures of the conductive structures 120. For example, the metallization structures of the conductive structures 120 may have sub-micron z-direction heights, whereas the top metal layers 140 and 144 may have z-direction heights of approximately 1 micron or greater. However, other z-direction heights for the metallization structures of the conductive structures 120 and for the top metal layers 140 and 144 are within the scope of the present disclosure.

The physically larger sizes of the top vias 138 and 142 and of the top metal layers 140 and 144 provide for lower sheet resistance and enable higher current signals to be handled at the top of the interconnect layer 106. The physically smaller sizes of the conductive structures 120 enable a higher density of conductive structures 120 to be included closer to the integrated circuit devices 112 in the device layer 104, which enables the integrated circuit devices 112 to be positioned closer together for higher integrated circuit device density in the device layer 104.

In some implementations, the ESLs 122, 126, 130, and 134 may include an alternating arrangement of materials. For example, the ESLs 122 and 130 may include silicon carbide (SiC), and the ESLs 126 and 134 may include a silicon nitride (SiₓN_{y} such as Si₃N₄). However, other combinations of materials for the ESLs 122, 126, 130, and 134 are within the scope of the present disclosure.

In some implementations, the ESL 122 may have a z-direction thickness that is included in a range of approximately 300 angstroms to approximately 800 angstroms. However, other values for the range are within the scope of the present disclosure. In some implementations, the ILD layer 124 may have a z-direction thickness that is included in a range of approximately 4000 angstroms to approximately 8000 angstroms. However, other values for the range are within the scope of the present disclosure. In some implementations, the ESL 126 may have a z-direction thickness that is included in a range of approximately 300 angstroms to approximately 700 angstroms. However, other values for the range are within the scope of the present disclosure. In some implementations, the ILD layer 128 may have a z-direction thickness that is included in a range of approximately 6000 angstroms to approximately 12000 angstroms. However, other values for the range are within the scope of the present disclosure. In some implementations, the ESL 130 may have a z-direction thickness that is included in a range of approximately 300 angstroms to approximately 800 angstroms. However, other values for the range are within the scope of the present disclosure. In some implementations, the ILD layer 132 may have a z-direction thickness that is included in a range of approximately 4000 angstroms to approximately 8000 angstroms. However, other values for the range are within the scope of the present disclosure. In some implementations, the ESL 134 may have a z-direction thickness that is included in a range of approximately 300 angstroms to approximately 700 angstroms. However, other values for the range are within the scope of the present disclosure. In some implementations, the ILD layer 136 may have a z-direction thickness that is included in a range of approximately 7000 angstroms to approximately 10000 angstroms. However, other values for the range are within the scope of the present disclosure.

The bonding layer 108 may be connected to the top metal layer 144 of the interconnect layer 106. The bonding layer 108 may include additional ESLs and dielectric layers, such as an ESL 146, a dielectric layer 148, an ESL 150, and/or a dielectric layer 152, among other examples. Moreover, the bonding layer 108 may include bonding vias 154 (e.g., that extend through the ESL 146 and/or the dielectric layer 148) and bonding pads 156 (e.g., that extend through the ESL 150 and/or the dielectric layer 152). The bonding vias 154 may be electrically connected and/or physically connected to the top metal layer 144, and the bonding pads 156 may be electrically connected and/or physically connected to the bonding vias 154.

The ESLs 146 and 150 may each include a silicon nitride (SiₓN_{y}), silicon carbide (SiC), silicon oxynitride (SiON), and/or another suitable dielectric material. The dielectric layers 148 and 152 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material.

In some implementations, the ESL 146 may have a z-direction thickness that is included in a range of approximately 500 angstroms to approximately 1000 angstroms. However, other values for the range are within the scope of the present disclosure. In some implementations, the dielectric layer 148 may have a z-direction thickness that is included in a range of approximately 4000 angstroms to approximately 9000 angstroms. However, other values for the range are within the scope of the present disclosure. In some implementations, the ESL 150 may have a z-direction thickness that is included in a range of approximately 800 angstroms to approximately 1600 angstroms. However, other values for the range are within the scope of the present disclosure. In some implementations, the dielectric layer 152 may have a z-direction thickness that is included in a range of approximately 6000 angstroms to approximately 12000 angstroms. However, other values for the range are within the scope of the present disclosure.

The bonding vias 154 include conductive structures that are elongated primarily in the z-direction. The bonding vias 154 may electrically couple the top metal layer 144 to the bonding pads 156. The bonding pads 156 include electrically conductive pads that are used for bonding the semiconductor device 102 to another semiconductor device to form a vertically stacked semiconductor package. The bonding vias 154 and bonding pads 156 include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The bonding layer 108 further includes a bonding dielectric layer 158 around the bonding pads 156. The bonding dielectric layer 158 may also be used to bond the semiconductor device 102 to another semiconductor device to form a vertically stacked semiconductor package. Thus, the combination of the bonding pads 156 and the bonding dielectric layer 158 enables the semiconductor device 102 to be bonded to another semiconductor device in a metal-to-metal bond and in a dielectric-to-dielectric bond. The bonding dielectric layer 158 may include one or more dielectric materials such as a silicon nitride (SiₓN_{y}), silicon carbide (SiC), silicon oxynitride (SiON), and/or another suitable dielectric material. In some implementations, a z-direction thickness of the bonding dielectric layer 158 may be included in a range of approximately 500 angstroms to approximately 1000 angstroms. However, other values for the range are within the scope of the present disclosure.

As further shown in FIG. 1, the semiconductor device 102 may include one or more capacitor structures 160. A capacitor structure 160 may include a trench capacitor structure that is included in and extends through at least a portion of the interconnect layer 106. In some implementations, the capacitor structure 160 may be included in and may extend through at least a portion of bonding layer 108, additionally or alternatively to extending through a portion of the interconnect layer 106.

The capacitor structure 160 may be electrically connected to a plurality of conductive structures in the interconnect layer 106. For example, a bottom of the capacitor structure 160 may be electrically connected to a conductive structure 120, and a top of the capacitor structure 160 may be electrically connected to a top via 142. As another example, the capacitor structure 160 may be electrically connected to a plurality of conductive structures 120 and/or to a plurality of top vias 142 at the top of the capacitor structure 160.

In some implementations, an integrated circuit device 112 is electrically coupled to a capacitor structure 160 to form a memory cell (e.g., a dynamic random access memory (DRAM) cell or another type of capacitor-based memory cell) in the semiconductor device 102. In some implementations, a capacitor structure 160 is configured to provide charge decoupling for one or more integrated circuit devices 112. In some implementations, a capacitor structure 160 is configured to store a charge (e.g., a photocurrent) for an integrated circuit device 112 (e.g., a pixel sensor) in the semiconductor device 102 to increase the full well capacity (FWC) of pixel sensors of the semiconductor device 102. In some implementations, a capacitor structure 160 is configured to support global shutter functionality of the semiconductor device 102. In some implementations, a capacitor structure 160 is configured to provide charge smoothing for organic light-emitting diode (OLED) display pixels of the semiconductor device 102, which enables a high brightness uniformity to be achieved for the OLED display pixels. In some implementations, a capacitor structure 160 is configured to perform another function in the semiconductor device 102.

As indicated above, FIG. 1 is provided as an example. Other examples may differ from what is described with regard to FIG. 1.

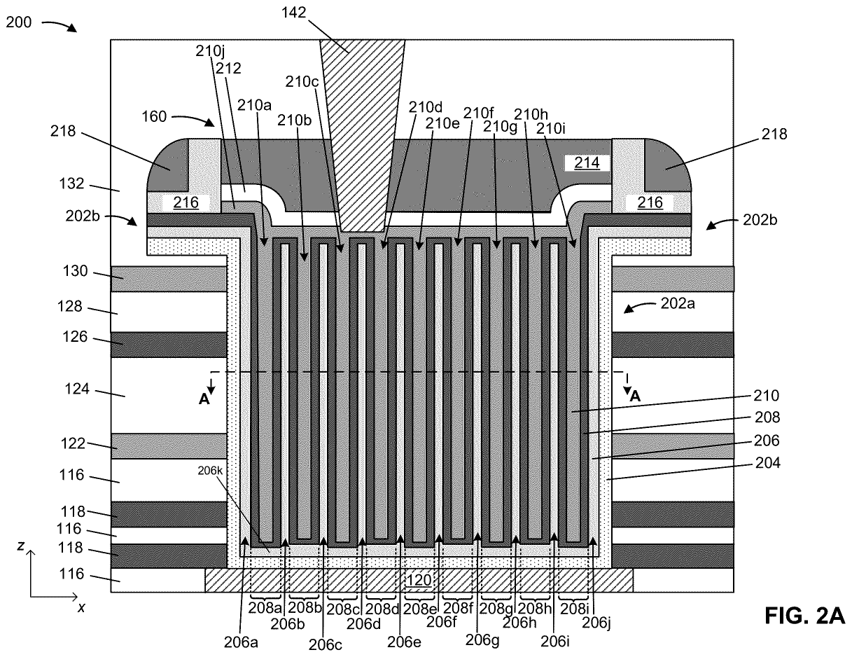

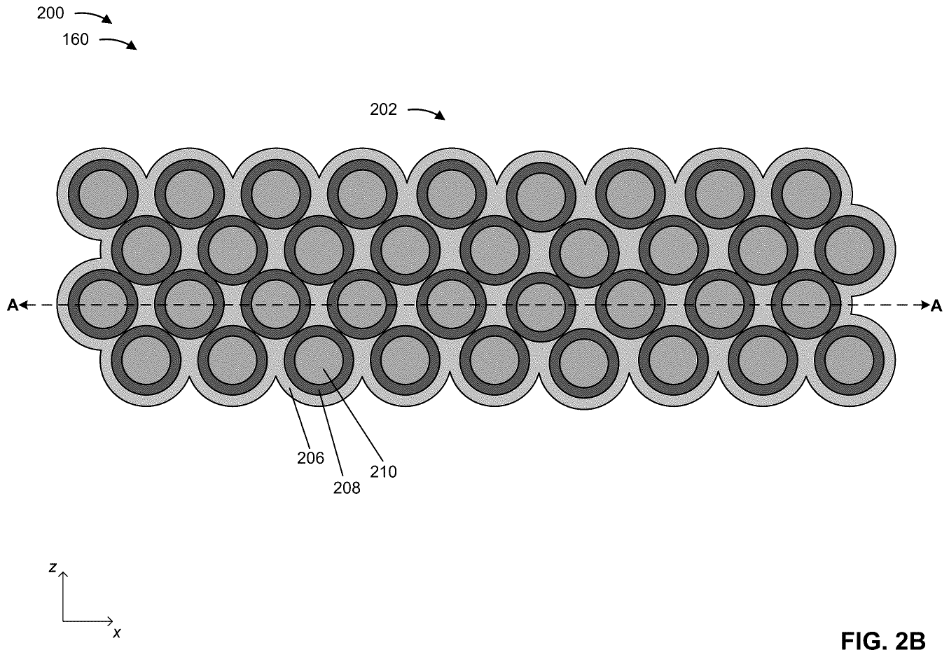

FIGS. 2A and 2B are diagrams of an example implementation 200 of a capacitor structure 160 described herein. FIG. 2A illustrates a cross-section view of the capacitor structure 160 along the x-direction in the semiconductor device 102. FIG. 2B illustrates a top view of the capacitor structure 160 in an x-y plane.

As shown in FIG. 2A, the capacitor structure 160 includes a main trench structure 202a that extends through one or more dielectric layers in the interconnect layer 106, and an upper extension region 202b above the main trench structure 202a. The main trench structure 202a corresponds to the main body of the capacitor structure 160 that was formed in a recess, whereas upper extension region 202b corresponds to a portion of the capacitor structure 160 that extends along a top surface of a portion of the ILD layer 132 prior to being encapsulated in the ILD layer 132.

A liner 204 may be included on the sidewalls, and a bottom surface of the main trench structure 202a may define the perimeter of the main trench structure 202a. The liner 204 may extend laterally outward from the main trench structure 202a in the upper extension region 202b. The liner 204 may include a tantalum nitride (TaN) barrier liner, a tantalum (Ta) liner, and/or another type of liner. The liner 204 may be included as an adhesion liner and/or as a barrier liner. For example, the liner 204 may be included as a copper (Cu) diffusion barrier to prevent, minimize, and/or otherwise reduce the likelihood of upward migration of copper atoms from the underlying conductive structure 120 to the capacitor structure 160.

A bottom electrode structure 206 may be included in the main trench structure 202a on the liner 204. The bottom electrode structure 206 may be electrically connected to an underlying conductive structure 120. The underlying conductive structure 120 may include a capacitor bottom metal (CBM) through via, a CBM pad, a CBM contact, and/or another type of interconnection structure. A portion of the underlying conductive structure 120 (e.g., a portion of the interconnection structure) that is located directly under the main trench structure 202a of the capacitor structure 160 may be referred to as a trench region of the underlying conductive structure 120.

The bottom electrode structure 206 includes a plurality of electrode walls 206a-206j that extend vertically (e.g., in the z-direction) from a base layer 206k of the bottom electrode structure 206. The base layer 206k extends from one end of the main trench structure 202a (and from one end of the trench region of the underlying conductive structure 120) to an opposing end of the main trench structure 202a (and to an opposing end of the trench region of the underlying conductive structure 120) along a horizontal plane (e.g., in an x-y plane), and is overlapped by the electrode walls 206a-206j. The electrode walls 206a-206j may be implemented as columns, pillars, hollow cylinders, hollow rectangular prisms, hollow square prisms, and/or another type of structure that primarily extends vertically (e.g., in the z-direction) from a base layer 206k of the bottom electrode structure 206. The electrode walls 206a and 206j may correspond to outer electrode walls of the bottom electrode structure 206 in that the electrode walls 206a and 206j extend along the sidewalls of the main trench structure 202a. The electrode walls 206b-206i may correspond to inner electrode walls in that the electrode walls 206b-206i are located inward in the main trench structure 202a from the sidewalls of the main trench structure 202a.

The areas between the electrode walls 206a-206j define trenches (e.g., secondary trenches) that are filled in with an insulator layer 208 of the capacitor structure 160 and with a top electrode structure 210 of the capacitor structure 160. The insulator layer 208 may include a plurality of connected approximately U-shaped cross-sectional segments 208a-208i that conform to the trenches defined by the electrode walls 206a-206j of the bottom electrode structure 206. The approximately U-shaped cross-sectional segments 208a-208i may be connected together at the tops of the approximately U-shaped cross-sectional segments 208a-208i (e.g., near the upper extension region 202b) such that the approximately U-shaped cross-sectional segments 208a-208i are connected together to form a continuous layer that extends through the main trench structure 202a. Portions of the insulator layer 208 may also laterally extend outward from the main trench structure 202a in the upper extension region 202b.

The top electrode structure 210 may include a plurality of electrode plugs 210a-210i (or columns, walls, pillars, and/or another type of conductive structures) that extend into the trenches defined by the electrode walls 206a-206j of the bottom electrode structure 206. The electrode plugs 210a-210i vertically extend (e.g., in the z-direction) from a base layer 210j of the top electrode structure 210. Thus, the electrode plugs 210a-210i extend downward from the base layer 210j of the top electrode structure 210, whereas the electrode walls 206a-206j of the bottom electrode structure 206 extend upward from the base layer 206k of the bottom electrode structure 206. Portions of top electrode structure 210 may also laterally extend outward from the main trench structure 202a in the upper extension region 202b. The main trench structure 202a (and the trench region of the underlying conductive structure 120) may be overlapped by the electrode plugs 210a-210i.

As further shown in FIG. 2A, the electrode walls 206a-206j and the electrode plugs 210a-210i may be arranged in a horizontally or laterally alternating manner. For example, in the x-direction, the electrode walls 206a-206j and the electrode plugs 210a-210i may be arranged as the electrode wall 206a horizontally or laterally adjacent to the electrode plug 210a, the electrode wall 206b horizontally or laterally adjacent to the electrode plug 210b, the electrode wall 206c horizontally or laterally adjacent to the electrode plug 210c, and so on. The quantities of the electrode walls 206a-206j and of the electrode plugs 210a-210i illustrated in FIG. 2A are an example, and other quantities are within the scope of the present disclosure.

In this way, the capacitor structure 160 includes an arrangement of sections of the bottom electrode structure 206, the insulator layer 208, and the top electrode structure 210 in the x-direction within the main trench structure 202a. For example, along the x-direction, the capacitor structure 160 may include an arrangement of the electrode wall 206a of the bottom electrode structure 206, the approximately U-shaped cross-sectional segment 208a of the insulator layer 208 in which the electrode plug 210a of the top electrode structure 210 extends, the electrode wall 206b of the bottom electrode structure 206, the approximately U-shaped cross-sectional segment 208b of the insulator layer 208 in which the electrode plug 210b of the top electrode structure 210 extends, the electrode wall 206c of the bottom electrode structure 206, the approximately U-shaped cross-sectional segment 208c of the insulator layer 208 in which the electrode plug 210c of the top electrode structure 210 extends, and so on.

The bottom electrode structure 206 (also referred to as a capacitor bottom metal (CBM)) and the top electrode structure 210 (also referred to as a capacitor top metal (CTM)) may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), tantalum (Ta), aluminum (Al), copper (Cu), gold (Au), titanium nitride (TiN), and/or tantalum nitride (TaN), among other examples. In some implementations, the bottom electrode structure 206 and the top electrode structure 210 include the same material or the same material composition. In some implementations, the bottom electrode structure 206 and the top electrode structure 210 include different materials or different material compositions.

The insulator layer 208 may include one or more electrically insulating materials. In some implementations, the insulator layer 208 includes one or more low-k dielectric materials such as silicon oxide (SiOₓ such as SiO₂). Additionally and/or alternatively, the insulator layer 208 may include one or more high-k dielectric materials such as zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), and/or hafnium oxide (HfOₓ such as HfO₂), among other examples. In some implementations, the insulator layer 208 is a multiple-layer stack that includes a plurality of dielectric layers. For example, the insulator layer 208 may include a ZrO₂/Al₂O₃/ZrO₂ (ZAZ) layer stack.

As further shown in FIG. 2A, the base layer 206k of the bottom electrode structure 206 may be electrically connected with an underlying conductive structure 120 in the interconnect layer 106. The base layer 210j of the top electrode structure 210 may be electrically connected with a top via 142 in the interconnect layer 106. The top via 142 may extend through one or more capping layers included over the base layer 210j of the top electrode structure 210. The capping layers may electrically insulate the top electrode structure 210 and/or may be used as hard mask layers for defining the upper extension region 202b of the capacitor structure 160.

The capping layers may include a capping layer 212, a capping layer 214, and/or another capping layer. The capping layers 212 and 214 may include an oxide-containing dielectric material such as silicon oxide (SiOₓ such as SiO₂), an oxynitride-containing dielectric material such as silicon oxynitride (SiON), a nitride-containing dielectric material such as silicon nitride (SiₓN_{y} such as Si₃N₄), and/or another suitable dielectric material. In some implementations, the capping layers 212 and 214 include the same material and/or the same material composition. In some implementations, the capping layers 212 and 214 include different materials and/or different material compositions.

As further shown in FIG. 2A, the capacitor structure 160 may include one or more sidewall spacers 216 and/or 218 on the sidewalls of the capping layers 212 and/or 214, and/or on sidewalls of the base layer 210j of the top electrode structure 210. The combination of the capping layers 212, 214 and the sidewall spacers 216, 218 may be used as a self-aligned mask when etching a layer to define the bottom electrode structure 206. The sidewall spacer 216 may include an oxide-containing dielectric material such as silicon oxide (SiOₓ such as SiO₂), among other examples. The sidewall spacer 218 may include a nitride-containing dielectric material such as silicon nitride (SiₓN_{y} such as Si₃N₄), among other examples.

As shown in FIG. 2B, the bottom electrode structure 206 may define a plurality of holes, plugs, or cylinder-shaped trenches in which the insulator layer 208 and the top electrode structure 210 extends. The holes may be arranged in a grid, a staggered grid (e.g., where the rows of the grid are staggered), and/or another top view layout.

As indicated above, FIGS. 2A and 2B are provided as examples. Other examples may differ from what is described with regard to FIGS. 2A and 2B.

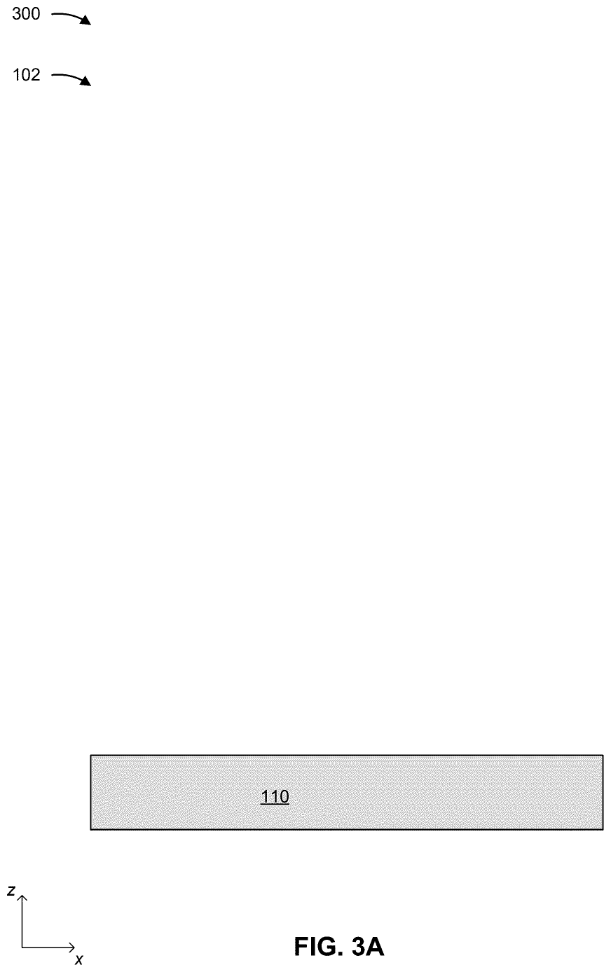

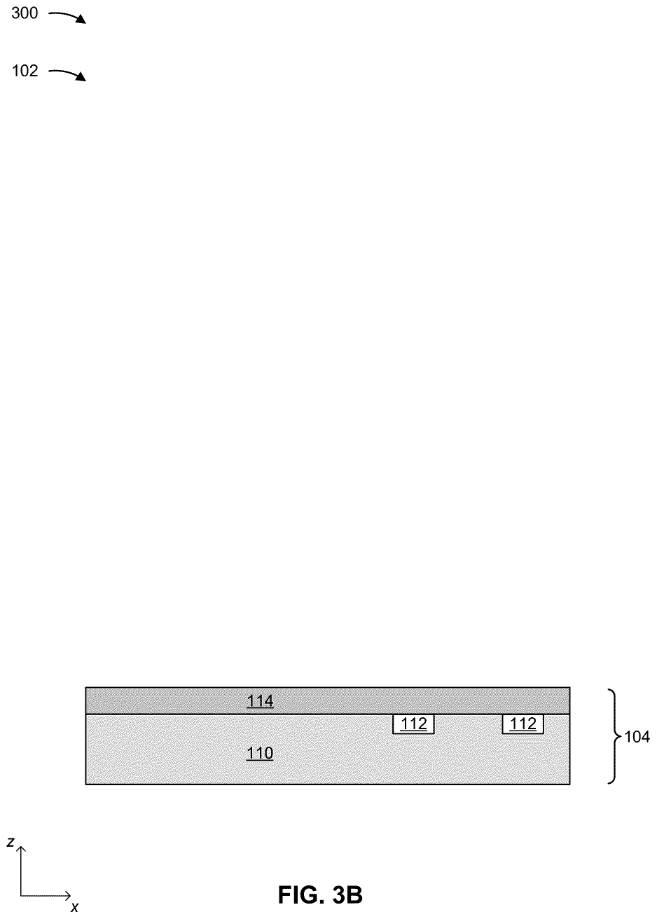

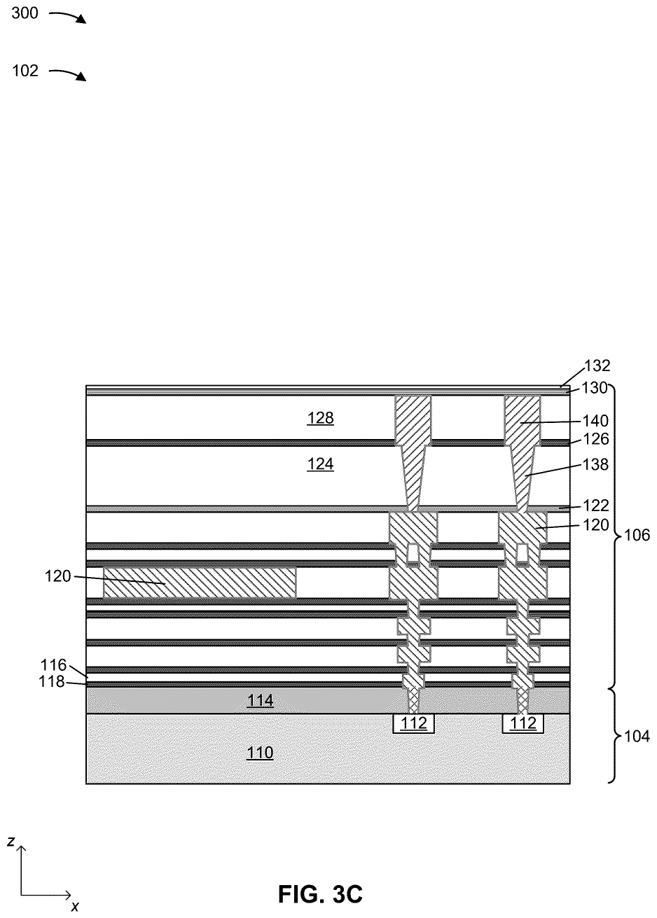

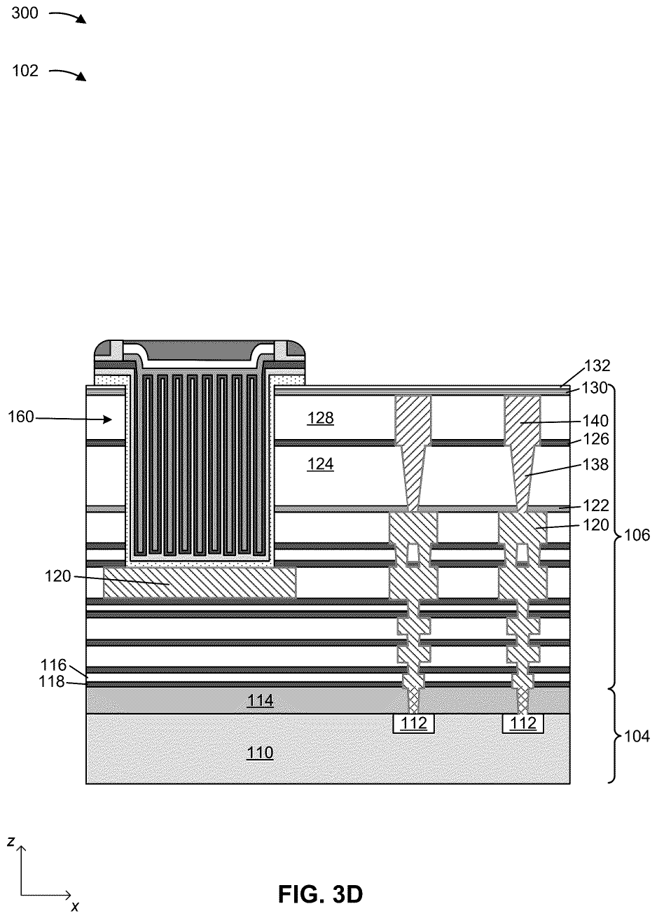

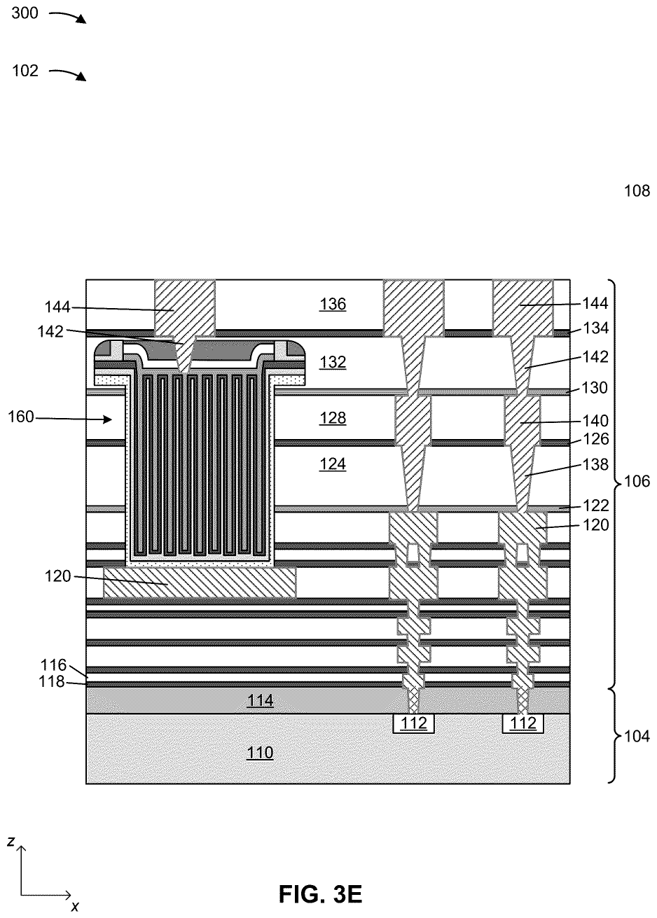

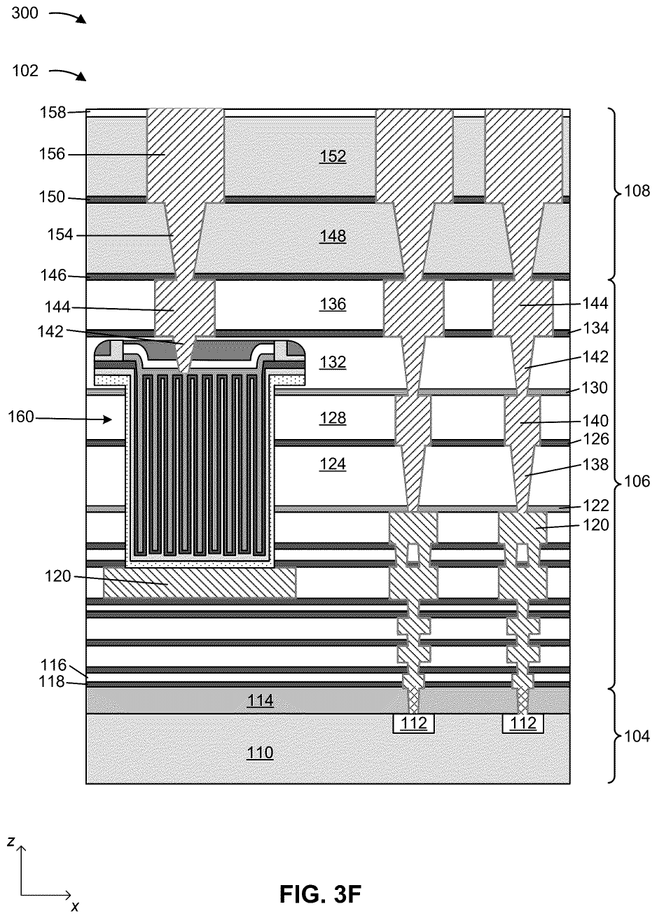

FIGS. 3A-3F are diagrams of an example implementation 300 of forming the semiconductor device 102 described herein. In some implementations, one or more of the semiconductor processing operations described in connection with FIGS. 3A-3F may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 3A, the substrate layer 110 may be provided. The substrate layer 110 may be provided in the form of a semiconductor wafer such as a silicon (Si) wafer, an SOI wafer, and/or another type of semiconductor work piece. The semiconductor device 102 may be formed on the semiconductor wafer with other semiconductor devices.

As shown in FIG. 3B, the integrated circuit devices 112 may be formed in and/or on the substrate layer 110 in the device layer 104 of the semiconductor device 102. One or more semiconductor processing tools may be used to form one or more portions of the integrated circuit devices 112. For example, an ion implantation tool may be used to dope one or more regions in the substrate layer 110 with one or more types of dopants to form well regions, implant regions, and/or other types of doped regions in the substrate layer 110 for the integrated circuit devices 112. As another example, a deposition tool may be used to perform various deposition operations to deposit layers and/or structures of the integrated circuit devices 112, and/or to deposit photoresist layers for etching the substrate layer 110 and/or portions of the deposited layers. As another example, an exposure tool may be used to expose the photoresist layers to form patterns in the photoresist layers. As another example, a developer tool may be used to develop the patterns in the photoresist layers. As another example, an etch tool may be used to etch the substrate layer 110 and/or portions of the deposited layers to form the integrated circuit devices 112. As another example, a planarization tool may be used to planarize portions of the integrated circuit devices 112. As another example, a plating tool may be used to deposit metal structures and/or layers of the integrated circuit devices 112.

As further shown in FIG. 3B, a deposition tool is used to deposit the dielectric layer 114 over and/or on the substrate layer 110 and over and/or on the integrated circuit devices 112. A deposition tool may be used to deposit the dielectric layer 114 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation, such as a chemical mechanical planarization (CMP) operation, to planarize the dielectric layer 114 after the dielectric layer 114 is deposited.

As shown in FIG. 3C, a first portion of the interconnect layer 106 of the semiconductor device 102 is formed above the dielectric layer 114. One or more deposition tools are used to deposit alternating layers of ILD layers 116 and ESLs 118 in the first portion of the interconnect layer 106 of the semiconductor device 102. In this way, the ILD layers 116 and ESLs 118 may be arranged in the z-direction in the semiconductor device 102. One or more deposition tools may be used to deposit each of the ILD layers 116 and each of the ESLs 118 using a PVD technique, an ALD technique, a CVD technique, an oxidation technique, and/or another suitable deposition technique. In some implementations, a planarization tool may be used to planarize the ILD layers 116 and/or the ESLs 118 after the ILD layers 116 and/or the ESLs 118 are deposited.

Prior to formation of the interconnect layer 106, contacts of the integrated circuit devices 112 may be formed through the dielectric layer 114. The contacts may be formed in recesses in the dielectric layer 114. In some implementations, a pattern in a photoresist layer is used to etch the dielectric layer 114 to form the recesses. In these implementations, a deposition tool may be used to form the photoresist layer on the dielectric layer 114. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 114 based on a pattern to form the recesses.

The contacts may be formed in the recesses. In some implementations, a contact (e.g., a gate contact) is formed on a gate structure of an integrated circuit device 112. In some implementations, a contact (e.g., a source/drain contact) is formed on a source/drain region of an integrated circuit device 112. A deposition tool may be used to deposit the material of the contacts in the recesses using a CVD technique, a PVD technique, an ALD technique, an electroplating technique, and/or another suitable deposition technique. The material of the contacts may be deposited in one or more deposition operations. In some implementations, a seed layer is first deposited, and the material of the contacts is deposited on the seed layer. In some implementations, a planarization tool is used to perform a planarization operation (e.g., a CMP operation) to planarize the contacts after the contacts are deposited such that the tops of the contacts are approximately co-planar with the top of the dielectric layer 114.

As further shown in FIG. 3C, a deposition tool, an exposure tool, a developer tool, an etch tool, a planarization tool, a plating tool, and/or another semiconductor processing tool may be used to perform various operations to form the conductive structures 120 in the first portion of the interconnect layer 106 of the semiconductor device 102. In some implementations, the first portion of the interconnect layer 106 may be formed in a plurality of layers. For example, an ILD layer 116 and an ESL 118 may be formed (e.g., using one or more deposition tools and/or one or more planarization tools), recesses may be formed in and/or through the ILD layer 116 and the ESL 118 (e.g., using an exposure tool, a developer tool, and/or an etch tool), and a first layer (e.g., the M0 layer) of conductive structures 120 (e.g., of metallization structures) may be formed in the ILD layer 116 and the ESL 118 (e.g., using one or more deposition tools and/or one or more planarization tools). Another ILD layer 116 and another ESL 118 may be formed, and a second layer (e.g., the V0 layer) of conductive structures 120 (e.g., of interconnect structures) may be formed in the ILD layer 116 and the ESL 118. Additional layers of conductive structures 120 may be formed in the interconnect layer 106 a similar manner.

One or more deposition tools may be used to deposit the conductive structures 120 using a PVD technique, an ALD technique, a CVD technique, an electroplating technique (e.g., an electro-chemical plating technique), and/or another suitable deposition technique. In some implementations, a planarization tool may be used to planarize the conductive structures 120 after the conductive structures 120 are deposited.

As further shown in FIG. 3C, the ESLs 122, 126, and 130 may be formed in the interconnect layer 106, and the ILD layers 124, 128, and 132 may be formed in the interconnect layer 106. One or more deposition tools are used to deposit the ESLs 122, 126, and 130, and the ILD layers 124, 128, and 132 using a PVD technique, an ALD technique, a CVD technique, an oxidation technique, and/or another suitable deposition technique. In some implementations, a planarization tool may be used to planarize the ESLs 122, 126, 130, and the ILD layers 124, 128, 132.

As further shown in FIG. 3C, a deposition tool, an exposure tool, a developer tool, an etch tool, a planarization tool, a plating tool, and/or another semiconductor processing tool may be used to perform various operations to form the top vias 138 and the top metal layers 140 in the first portion of the interconnect layer 106 of the semiconductor device 102. In some implementations, the ESL 122 and the ILD layer 124 may be formed, recesses may be formed in and/or through the ESL 122 and the ILD layer 124 (e.g., using an exposure tool, a developer tool, and/or an etch tool), and the top vias 138 may be formed in the recesses (e.g., using one or more deposition tools and/or one or more planarization tools). In some implementations, the ESL 126 and the ILD layer 128 may be formed, recesses may be formed in and/or through the ESL 126 and the ILD layer 128 (e.g., using an exposure tool, a developer tool, and/or an etch tool), and the top metal layers 140 may be formed in the recesses (e.g., using one or more deposition tools and/or one or more planarization tools). In some implementations, the ESL 130 and the ILD layer 132 may be formed, recesses may be formed in and/or through the ESL 130 and the ILD layer 132 (e.g., using an exposure tool, a developer tool, and/or an etch tool), and the top vias 142 may be formed in the recesses (e.g., using one or more deposition tools and/or one or more planarization tools). In some implementations, the ESL 134 and the ILD layer 136 may be formed, recesses may be formed in and/or through the ESL 134 and the ILD layer 136 (e.g., using an exposure tool, a developer tool, and/or an etch tool), and the top metal layers 144 may be formed in the recesses (e.g., using one or more deposition tools and/or one or more planarization tools).

One or more deposition tools may be used to deposit the top vias 138, 142 and the top metal layers 140, 144 using a PVD technique, an ALD technique, a CVD technique, an electroplating technique (e.g., an electro-chemical plating technique), and/or another suitable deposition technique. In some implementations, a planarization tool may be used to planarize the top vias 138, 142 and the top metal layers 140, 144 after the top vias 138, 142 and the top metal layers 140, 144 are deposited.

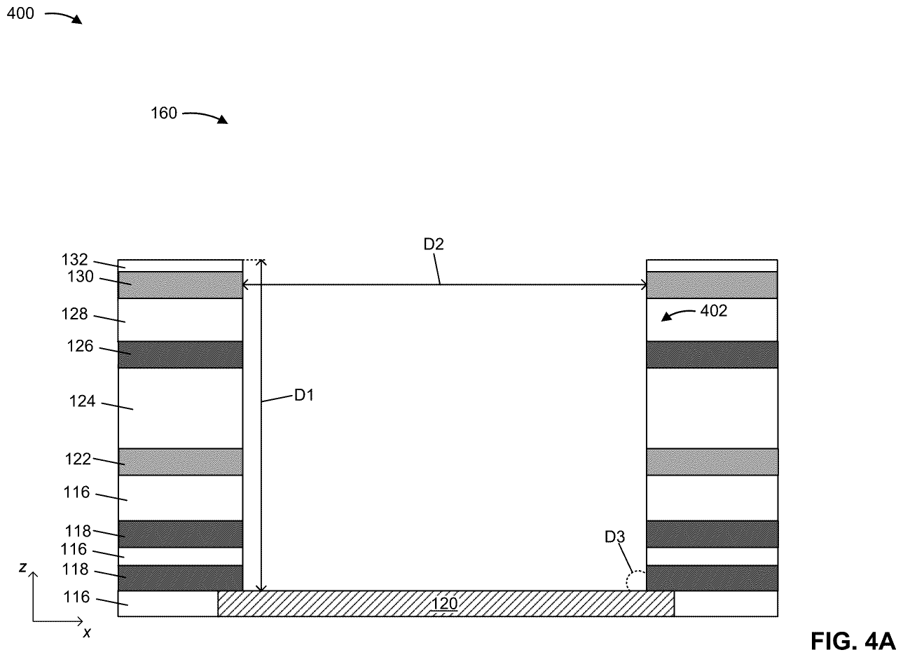

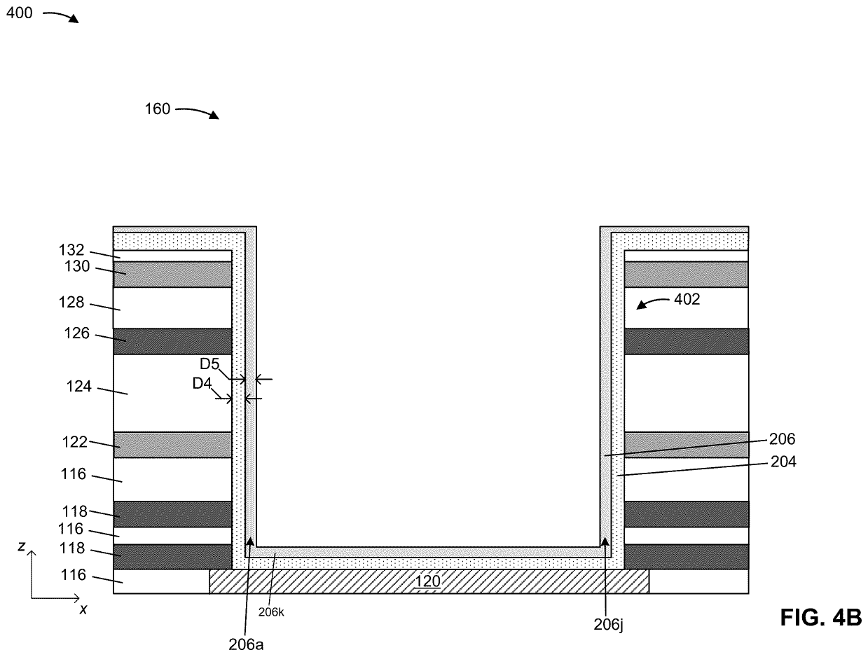

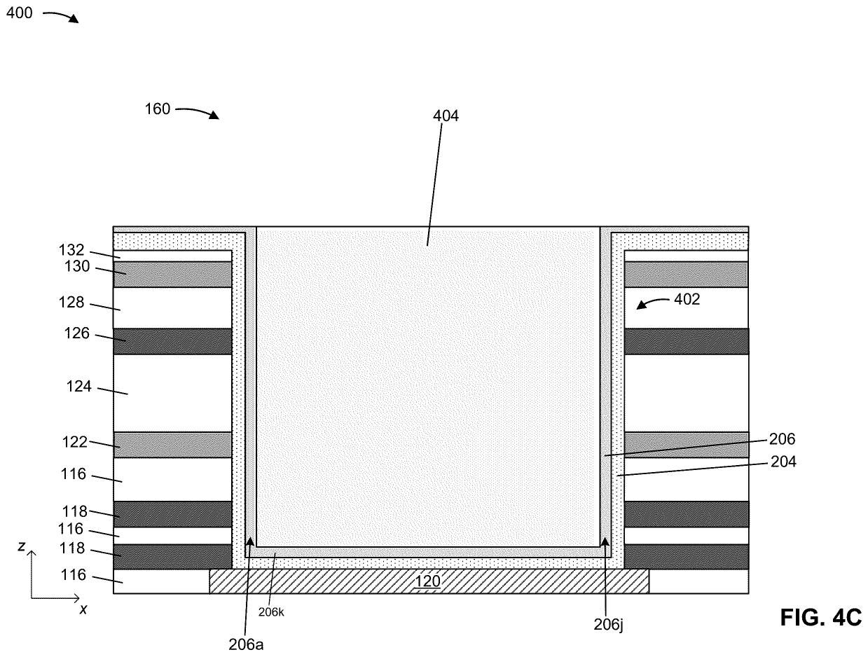

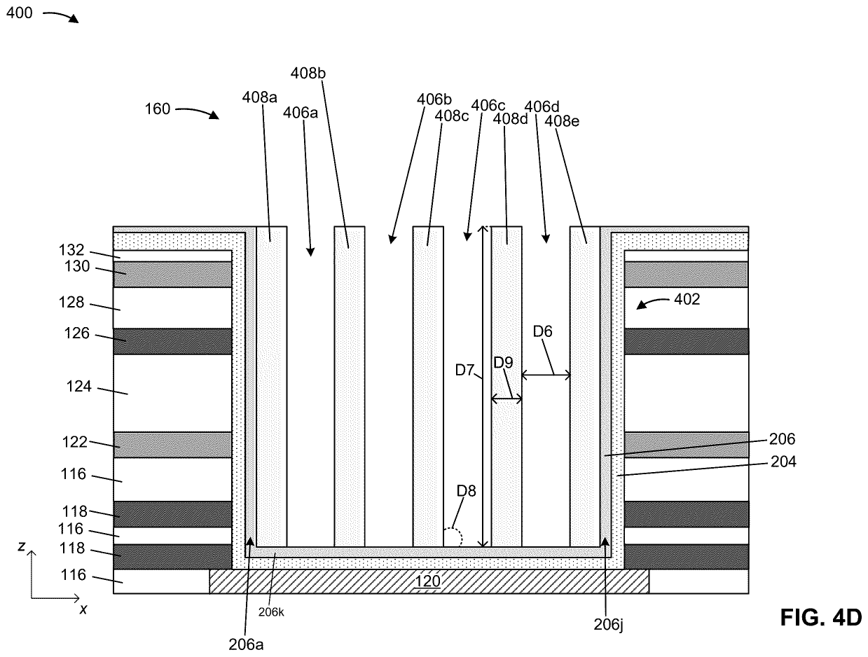

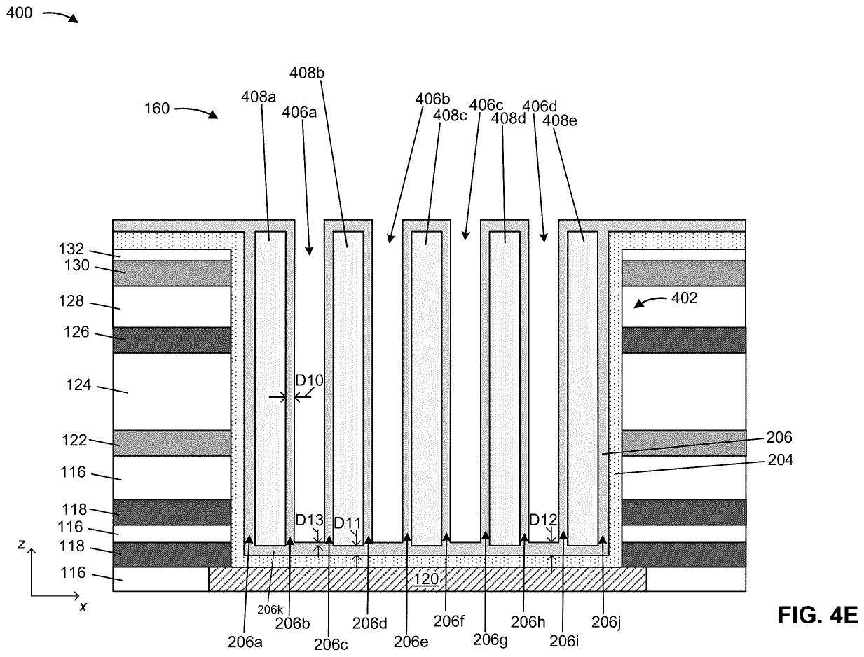

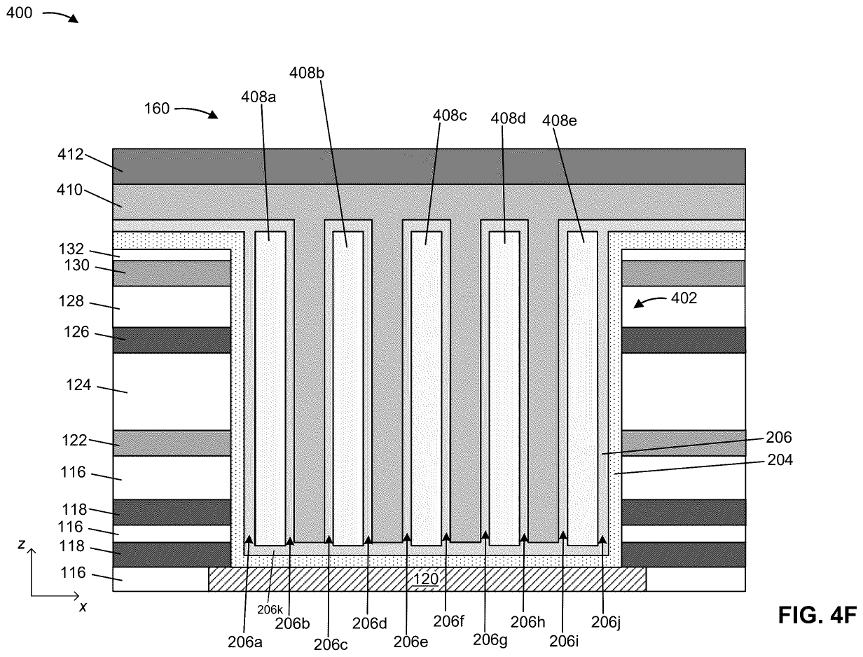

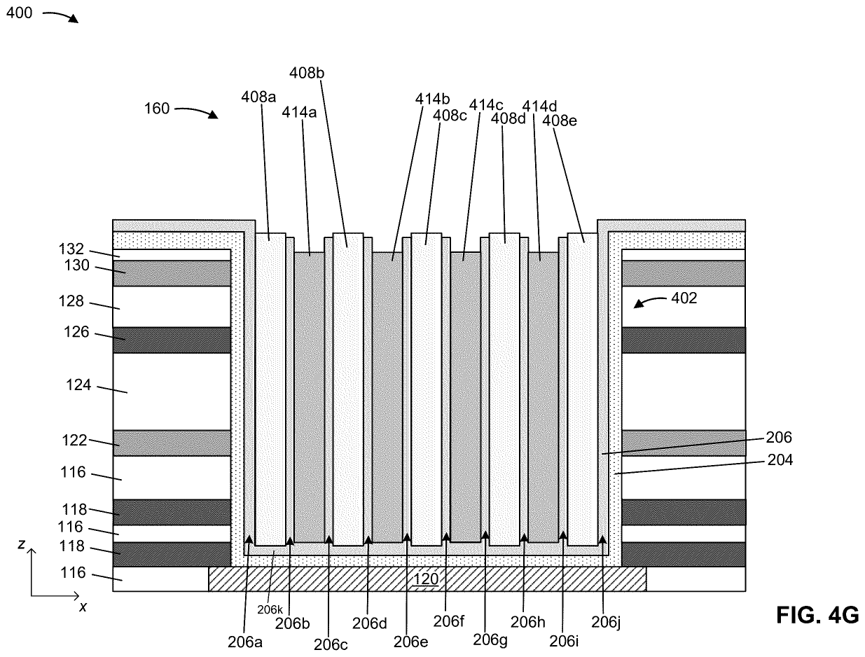

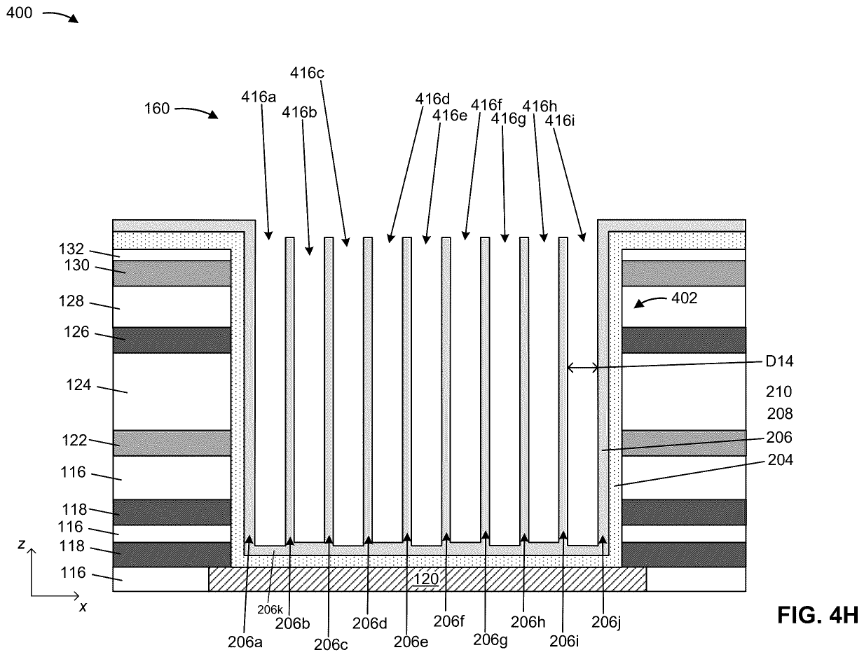

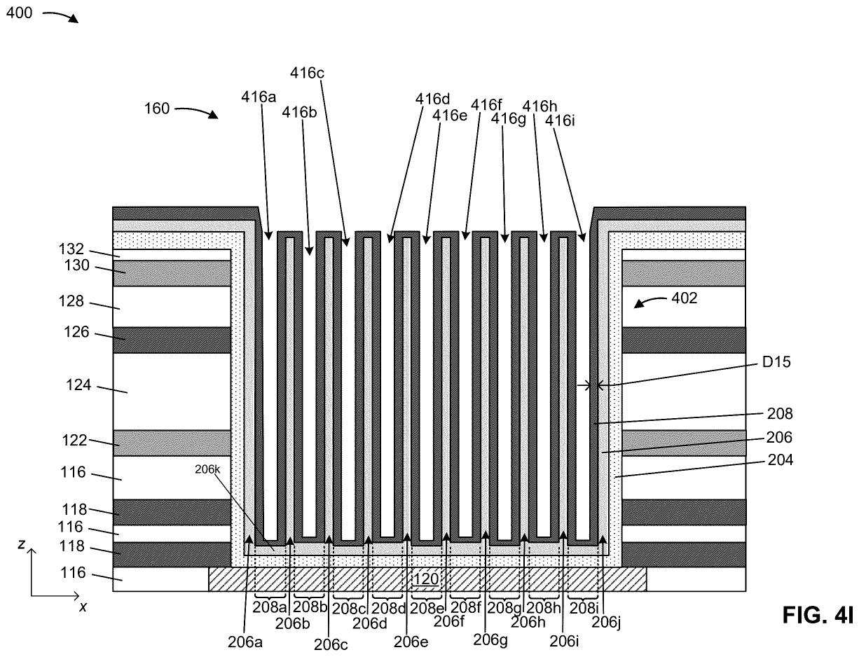

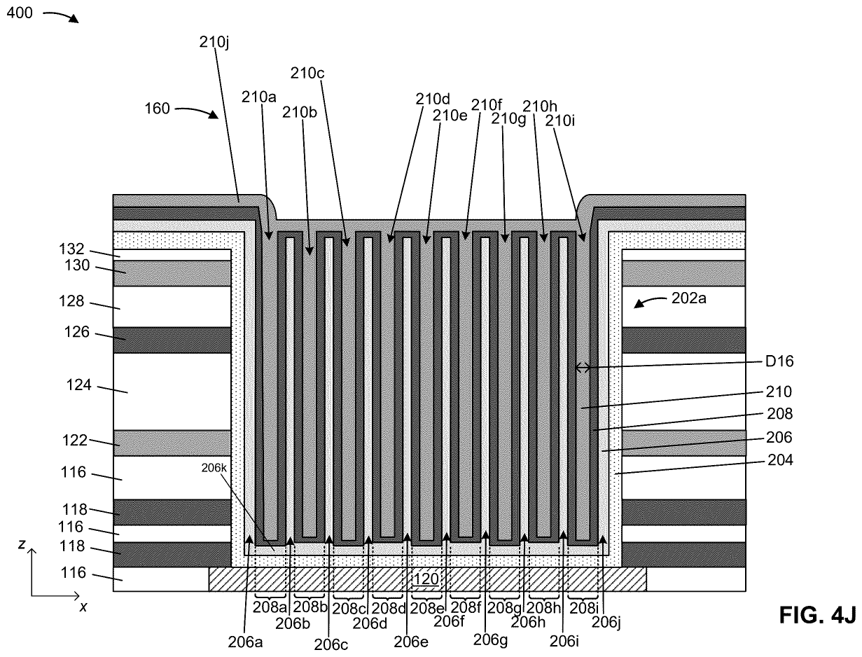

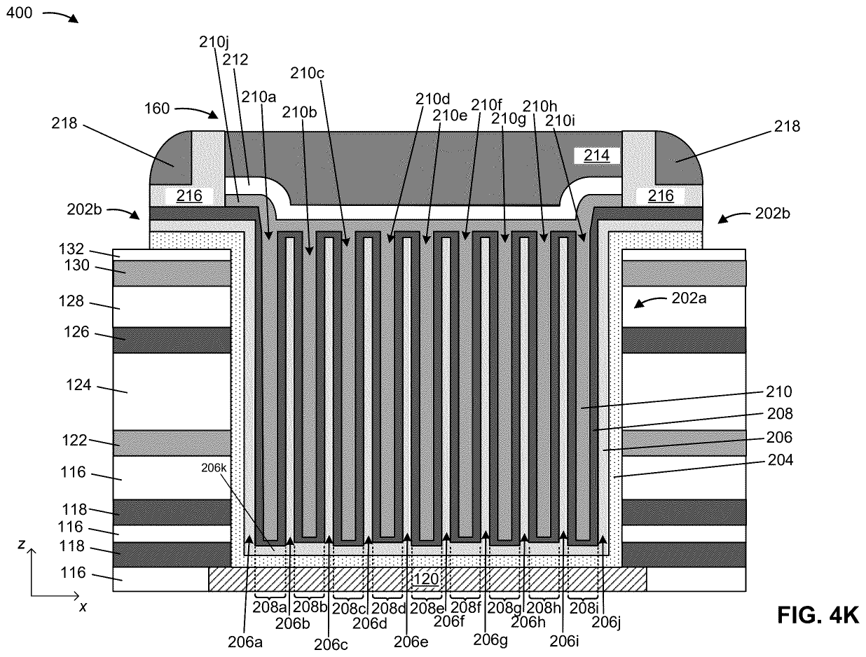

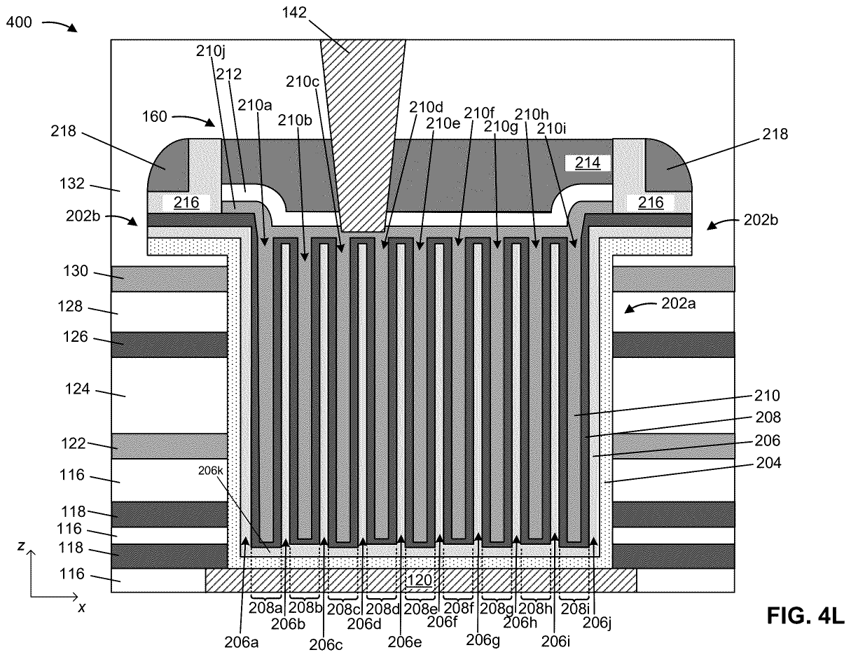

As shown in FIG. 3D, a capacitor structure 160 may be formed in the interconnect layer 106 of the semiconductor device 102. The capacitor structure 160 may be formed in a recess through one or more dielectric layers in the interconnect layer 106, such as one or more ILD layers 116, one or more ESLs 118, the ESL 122, the ILD layer 124, the ESL 126, the ILD layer 128, the ESL 130, and/or the ILD layer 132, among other examples. The recess may extend through the dielectric layer(s) to an underlying conductive structure 120 in the interconnect layer 106 such that the capacitor structure 160 is formed on, and in electrical connection with, the conductive structure 120. An example implementation of forming the capacitor structure 160 is illustrated and described in connection with FIGS. 4A-4L.

As shown in FIG. 3E, additional material of the ILD layer 132 may be formed such that the top of the capacitor structure 160 is encapsulated in the ILD layer 132. A deposition tool may be used to deposit the additional material of the ILD layer 132 using a PVD technique, an ALD technique, a CVD technique, an oxidation technique, and/or another suitable deposition technique. In some implementations, a planarization tool may be used to planarize the ILD layer 132 after the additional material of the ILD layer 132 is deposited.

As further shown in FIG. 3E, the ESL 134 and the ILD layer 136 may be formed, recesses may be formed in and/or through the ESL 134 and the ILD layer 136 (e.g., using an exposure tool, a developer tool, and/or an etch tool), and the top metal layers 144 may be formed in the recesses (e.g., using one or more deposition tools and/or one or more planarization tools).

One or more deposition tools may be used to deposit the top vias 142 and the top metal layers 144 using a PVD technique, an ALD technique, a CVD technique, an electroplating technique (e.g., an electro-chemical plating technique), and/or another suitable deposition technique. In some implementations, a planarization tool may be used to planarize the top vias 142 and the top metal layers 144 after the top vias 142 and the top metal layers 144 are deposited.

As further shown in FIG. 3E, a top via 142 may be formed such that the top via 142 lands on, and is in electrical connection with, the capacitor structure 160. The top via 142 electrically connects the capacitor structure 160 to a top metal layer 144 and to other structures in the semiconductor device 102.

As shown in FIG. 3F, the ESLs 146 and 150 of the bonding layer 108, the dielectric layers 148 and 152 of the bonding layer 108, and the bonding dielectric layer 158 of the bonding layer 108 may be formed above the interconnect layer 106. Bonding vias 154 may be formed in and/or through the ESL 146 and the dielectric layer 148, and may be formed on top metal layers 144. Bonding pads 156 may be formed in and/or through the ESL 150, the dielectric layer 152, and/or the bonding dielectric layer 158, and may be formed on the bonding vias 154.

One or more deposition tools may be used to deposit the ESL 146, the dielectric layer 148, the ESL 150, the dielectric layer 152, and/or the bonding dielectric layer 158 using a PVD technique, an ALD technique, a CVD technique, an oxidation technique, and/or another suitable deposition technique. In some implementations, a planarization tool may be used to perform a planarization operation (e.g., a CMP operation) to planarize the ESL 146, the dielectric layer 148, the ESL 150, the dielectric layer 152, and/or the bonding dielectric layer 158.

In some implementations, the bonding vias 154 and the bonding pads 156 may be formed in dual damascene recesses. For example, a first etch operation may be performed to form a trench portion of the dual damascene recesses, and a second etch operation may be performed to form a via portion of the dual damascene recesses. As another example, a first etch operation may be performed to form a via portion of the dual damascene recesses, and a second etch operation may be performed to form a trench portion of the dual damascene recesses. The bonding vias 154 may be formed in the via portions of the dual damascene recesses, and the bonding pads 156 may be formed in the trench portions of the dual damascene recesses.

A deposition tool may be used to deposit the bonding vias 154 and bonding pads 156 using a CVD technique, a PVD technique, an ALD technique, an electroplating technique, and/or another suitable deposition technique. The bonding vias 154 and bonding pads 156 may be deposited in one or more deposition operations. In some implementations, a seed layer is first deposited in the dual damascene recesses, and the bonding vias 154 and bonding pads 156 are deposited on the seed layer. In some implementations, a liner layer (e.g., an adhesion liner, a barrier liner) is first deposited in the dual damascene recesses, and the bonding vias 154 and bonding pads 156 are deposited on the liner layer. The liner layer may include a suitable liner material such as a tantalum nitride (TaN) and/or titanium nitride (TiN), among other examples. In some implementations, a planarization tool is used to perform a planarization operation (e.g., a CMP operation) to planarize the bonding pads 156 after the bonding vias 154 and bonding pads 156 are deposited.

As indicated above, FIGS. 3A-3F are provided as an example. Other examples may differ from what is described with regard to FIGS. 3A-3F.

FIGS. 4A-4L are diagrams of an example implementation 400 of forming a capacitor structure 160 described herein. In some implementations, one or more of the operations described in connection with FIGS. 4A-4L may be performed in connection with the process for forming the semiconductor device 102 illustrated and described in connection with FIGS. 3A-3F. In some implementations, one or more of the semiconductor processing operations described in connection with FIGS. 4A-4L may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 4A, a recess 402 is formed through one or more dielectric layers in the interconnect layer 106, such as one or more ILD layers 116, one or more ESLs 118, the ESL 122, the ILD layer 124, the ESL 126, the ILD layer 128, the ESL 130, and/or the ILD layer 132, among other examples. The recess 402 may extend through the dielectric layer(s) to an underlying conductive structure 120 in the interconnect layer 106 such that the capacitor structure 160 is formed on, and in electrical connection with, the conductive structure 120.

The recess 402 may be formed to have a relatively low aspect ratio, which is a ratio of a z-direction depth of the recess 402 (dimension D1) to a width (e.g., an x-direction width, a y-direction width) of the recess 402 (dimension D2). For example, the aspect ratio of the recess 402 may be included in a range of approximately 2:1 to approximately 10:1. However, other values and ranges are within the scope of the present disclosure. In some implementations, the recess 402 is formed to have an aspect ratio of greater than approximately 10:1 and up to approximately 25:1.

In some implementations, the z-direction depth of the recess 402 (dimension D1) may be included in a range of approximately 160 nanometers to approximately 1650 nanometers. However, other values and ranges are within the scope of the present disclosure. In some implementations, the width (e.g., an x-direction width, a y-direction width) of the recess 402 (dimension D2) may be included in a range of approximately 65 nanometers to approximately 80 nanometers. However, other values and ranges are within the scope of the present disclosure.

In some implementations, the recess 402 may have a sidewall angle (dimension D3—an angle between the bottom surface of the recess 402 and a sidewall of the recess 402) that is included in a range of approximately 95 degrees to approximately 110 degrees. However, other values and ranges are within the scope of the present disclosure.

As shown in FIG. 4B, a liner 204 is formed in the recess 402. The liner 204 may be conformally deposited on the sidewalls and the bottom surface of the recess 402. Portions of the liner 204 may also be deposited over the top surface of the ILD layer 132. In some implementations, a conformal CVD technique and/or an ALD technique is used to deposit the liner 204. In some implementations, another deposition technique is used to deposit the liner 204.

The liner 204 may be deposited to a thickness (dimension D4) that is included in a range of approximately 100 angstroms to approximately 1000 angstroms. However, other values and ranges are within the scope of the present disclosure. If the thickness of the liner 204 is less than approximately 100 angstroms, voids and/or other discontinuities may occur in the liner 204, and the liner 204 may not provide sufficient protection against copper migration. If the thickness of the liner 204 is greater than approximately 1000 angstroms, the area within the recess 402 may be reduced, providing less area for the capacitor structure 160 in the recess 402. However, other values, and ranges other than approximately 100 angstroms to approximately 1000 angstroms are within the scope of the present disclosure.

As further shown in FIG. 4B, a first portion of a bottom electrode structure 206 is formed in the recess 402 on the liner 204. In particular, the electrode walls 206a and 206j (e.g., the outer electrode walls) of the bottom electrode structure 206 may be formed on the sidewalls of the recess 402, and the base layer 206k of the bottom electrode structure 206 may be formed on the bottom of the recess 402. The first portion of the bottom electrode structure 206 may also be formed on the top surface of the ILD layer 132.

The first portion of the bottom electrode structure 206 may be conformally deposited using a conformal CVD technique and/or an ALD technique. In some implementations, another deposition technique is used to deposit the first portion of the bottom electrode structure 206. The first portion of the bottom electrode structure 206 may be formed to a thickness (dimension D5) that is included in a range of approximately 200 angstroms to approximately 500 angstroms. However, other values and ranges are within the scope of the present disclosure.

As shown in FIG. 4C, the remaining area in the recess 402 is filled in with a dielectric plug 404 such as a silicon dioxide (SiO₂) plug. Alternatively, the remaining area in the recess 402 may be filled in with a semiconductor plug (e.g., a silicon (Si) plug, a polysilicon plug). A deposition tool may be used to deposit the dielectric plug 404 using a PVD technique, an ALD technique, a CVD technique, an oxidation technique, and/or another suitable deposition technique. The dielectric plug 404 may be deposited in one or more deposition operations.

As further shown in FIG. 4C, a planarization tool may be used to perform a planarization operation (e.g., a CMP operation) to planarize the dielectric plug 404 after the dielectric plug 404 is deposited. The planarization operation may be stopped once the portion of the bottom electrode structure 206 that extends along the top of the ILD layer 132 is reached. In this way, the top surface of the dielectric plug 404 may be approximately co-planar with the top surface of the portion of the bottom electrode structure 206 that extends along the top of the ILD layer 132. Additionally and/or alternatively, an etch tool may be used to perform an etch-back operation to remove excess material from the dielectric plug 404.

As shown in FIG. 4D, the dielectric plug 404 may be etched to form recesses 406a-406d in the dielectric plug 404. The recesses 406a-406d may extend through the dielectric plug 404 to the underlying base layer 206k of the bottom electrode structure 206. The remaining portions of the dielectric plug 404 may correspond to dielectric plugs 408a-408e that define the recesses 406a-406d. The quantities of recesses 406a-406d and dielectric plugs 408a-408e illustrated in FIG. 4D are an example, and other quantities are within the scope of the present disclosure.

In some implementations, a pattern in a photoresist layer is used to etch the dielectric plug 404 to form the recesses 406a-406d. In these implementations, a deposition tool may be used to form the photoresist layer on the dielectric plug 404 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the dielectric plug 404 based on the pattern to form the recesses 406a-406d. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric plug 404 based on a pattern.

In some implementations, a deep reactive ion etch technique (sometimes referred to as a “BOSCH” etch technique) may be used to achieve the high aspect ratio (e.g., a ratio of approximately 25:1 to approximately 50:1 or greater) for the recesses 406 a-406d. A deep reactive ion etch technique is a cyclic etch technique in which a plurality of deposition and etch cycles are performed using protective liners to minimize lateral etching. For example, a deep reactive ion etch cycle may include etching the recesses 406a-406d to a first depth, forming a protective liner on the sidewalls and bottom surface of the recesses 406a-406d, etching the protective liner to remove the protective liner from the bottom surface of the recesses 406a-406d, and etching the bottom of the recesses 406a-406d to increase the depth of the recesses 406a-406d to a second depth while the protective liner protects the sidewalls of the recesses 406a-406d from lateral etching. Additional cycles may be performed to achieve a particular depth for the recesses 406a-406d.

As shown in FIG. 4D, the recesses 406a-406d may be formed to have a lateral (e.g., x-direction, y-direction) width (dimension D6), a vertical (e.g., z-direction) depth (dimension D7), a sidewall angle (dimension D8), and/or a lateral spacing (dimension D9). In some implementations, the lateral width (dimension D6) of a recess 406a-406d is included in a range of approximately 500 angstroms to approximately 1200 angstroms. In some implementations, a vertical depth (dimension D7) of a recess 406a-406d is included in a range of approximately 200nanometers to approximately 1650 nanometers. In some implementations, a sidewall angle (dimension D8) of a recess 406 a-406d is included in a range of approximately 90 degrees to approximately 92 degrees. In some implementations, a lateral spacing between adjacent pairs of recesses 406a-406d (which may correspond to a lateral thickness of a dielectric plug 408a-408e) is included in a range of approximately 800 angstroms to approximately 1600 angstroms. However, other values and ranges for these dimensions are within the scope of the present disclosure.

As shown in FIG. 4E, a second portion of a bottom electrode structure 206 is formed in the recesses 406a-406d and on the tops of the dielectric plugs 408a-408e. The second portion of the bottom electrode structure 206 may be conformally deposited using a conformal CVD technique and/or an ALD technique. In some implementations, another deposition technique is used to deposit the second portion of the bottom electrode structure 206.

The second portion of the bottom electrode structure 206 may include the electrode walls 206b-206i (e.g., inner electrode walls) and additional material of the base layer 206k. The first portion and the second portion of the bottom electrode structure 206 merge or connect at the tops of the electrode walls 206a-206j such that adjacent pairs of the electrode walls 206a-206j are connected together. For example, the tops of the electrode walls 206a and 206b may be connected together (e.g., across the dielectric plug 408a), the tops of the electrode walls 206c and 206d may be connected together (e.g., across the dielectric plug 408b), the tops of the electrode walls 206e and 206f may be connected together (e.g., across the dielectric plug 408c), the tops of the electrode walls 206g and 206 h may be connected together (e.g., across the dielectric plug 408d), and/or the tops of the electrode walls 206 i and 206 j may be connected together (e.g., across the dielectric plug 408e).

The electrode walls 206b-206i may be formed on the sidewalls of the recesses 406a-406d, which may correspond to the sidewalls of the dielectric plugs 408a-408e. In some implementations, the electrode walls 206b-206i are formed to a thickness (dimension D10) that is included in a range of approximately 200 angstroms to approximately 300 angstroms. However, other values and ranges are within the scope of the present disclosure.

The additional material of the base layer 206k may be deposited at the bottom of the recesses 406a-406d. The dielectric plugs 408a-408e may block the additional material of the base layer 206k from being deposited on non-exposed portions of the base layer 206k. As a result, the base layer 206k includes first segments under the dielectric plugs 408a-408e that have a first thickness (dimension D11) and second segments exposed through the recesses 406a-406dthat have a second thickness (dimension D12), where the second thickness is greater than the first thickness (D12>D11) by a difference corresponding to a dimension D13. In some implementations, the difference between the dimension D12 and the dimension D11 (corresponding to the dimension D13) may be included in a range of approximately 200 angstroms to approximately 300 angstroms. However, other values and ranges are within the scope of the present disclosure.

As shown in FIG. 4F, a masking layer 410 and a photoresist layer 412 may be formed. The masking layer 410 may be formed in the recesses 406a-406d and may extend across the surface of the ILD layer 132. The photoresist layer 412 may be formed on the masking layer 410.

The masking layer 410 may include an advanced patterning film (APF) layer, a bottom anti-reflective coating (BARC), and/or another suitable masking material. The masking layer 410 may include an amorphous carbon material, a silicon oxide material (e.g., SiOₓ such as SiO₂), silicon oxynitride (SiON), a polymer, and/or another suitable material. A deposition tool may be used to deposit the masking layer 410 using a PVD technique, a CVD technique, an ALD technique, a spin-coating technique, and/or another suitable deposition technique.

The photoresist layer 412 may include an organic photoresist material, an inorganic photoresist material, and/or another suitable photoresist material. A deposition tool may be used to deposit the photoresist layer 412 using a spin-coating technique, and/or another suitable deposition technique.

As shown in FIG. 4G, the masking layer 410 may be etched to form patterning plugs 414a-414d in the recesses 406a-406d, respectively. The patterning plugs 414a-414d may be used in connection with the dielectric plugs 408a-408e to etch the portions of the bottom electrode structure 206 that connect the tops of the electrode walls 206a-206j.

In some implementations, the masking layer 410 is consumed during etching of the portions of the bottom electrode structure 206 that connect the tops of the electrode walls 206a-206j. For example, a pattern may be formed in the photoresist layer 412 (e.g., using lithography techniques and developer techniques), and an etch tool may be used to etch the masking layer 410 until the portions of the bottom electrode structure 206 that connect the tops of the electrode walls 206a-206j are exposed through the masking layer 410 (which results in formation of the patterning plugs 414a-414d). The etching operation may continue until the portions of the bottom electrode structure 206 that connect the tops of the electrode walls 206a-206j are removed, such that the electrode walls 206a-206j are disconnected from each other at the tops of the electrode walls 206a-206j. This may result in further material removal from the patterning plugs 414a-414d. Accordingly, the top surfaces of the patterning plugs 414a-414d may be lower than the top surfaces of the dielectric plugs 408a-408e.

As shown in FIG. 4H, the dielectric plugs 408a-408e and the patterning plugs 414a-414d are removed from the recess 402. Removal of the dielectric plugs 408a-408e and the patterning plugs 414a-414d leaves behind recesses 416a-416i (e.g., secondary recesses or secondary trenches) defined by the electrode walls 206a-206j and the base layer 206k of the bottom electrode structure 206. Using the electrode walls 206a-206j and the base layer 206k of the bottom electrode structure 206 to define the recesses 416a-416i reduces the likelihood of collapse of the recesses 416a-416i compared to a case where the recesses 416a-416i were formed from the dielectric layers in the interconnect layer 106. The distance or spacing between adjacent pairs of the electrode walls 206a-206j (dimension D14 - which may also correspond to a lateral width of the recess 416 a-416i) may be included in a range of approximately 500 angstroms to approximately 1000 angstroms. However, other values and ranges are within the scope of the present disclosure.

In some implementations, the dielectric plugs 408a-408e and the patterning plugs 412a-412d are removed in the same operation, such as by etching (e.g., wet etching, plasma-based etching, gas-based etching). In some implementations, the dielectric plugs 408a-408e and the patterning plugs 414a-414d are removed in separate operations. For example, the dielectric plugs 408a-408e may be removed by etching, and the patterning plugs 414a-414d may be removed by plasma ashing, chemical stripping, and/or another photoresist removal technique. In some implementations, the dielectric plugs 408a-408e are removed first, followed by removal of the patterning plugs 414a-414d. In some implementations, the patterning plugs 414a-414d are removed first, followed by removal of the dielectric plugs 408a-408e.

An etchant such as vaporized hydrofluoric acid (VHF) or a liquid-based hydrofluoric acid (HF) may be used to etch the dielectric plugs 408a-408e and/or the patterning plugs 414a-414d with minimal to no etching of the electrode walls 206a-206j and the base layer 206k of the bottom electrode structure 206. The hydrofluoric acid-based etchant may be used to selectively etch oxide-based materials (e.g., such as the materials of the dielectric plugs 408a-408e and/or of the patterning plugs 414a-414d) with minimal to no etching of the material of the bottom electrode structure 206 (e.g., titanium nitride (TiN), among other examples).

As shown in FIG. 4I, the insulator layer 208 may be deposited on the bottom electrode structure 206 in the recess 402. In particular, the insulator layer 208 is deposited on the sidewalls of the recesses 416a-416i (corresponding to the electrode walls 206a-206j) and on the bottom surfaces of the recesses 416a-416i (corresponding to the base layer 206k). This results in formation of the approximately U-shaped cross-sectional segments 208a-208i of the insulator layer 208 that are connected at the tops of the approximately U-shaped cross-sectional segments 208a-208i.

In some implementations, a deposition tool is used to conformally deposit the insulator layer 208 using a conformal CVD technique and/or an ALD technique. In some implementations, another deposition technique is used to deposit the insulator layer 208. The insulator layer 208 may be deposited to a thickness (dimension D15) that is included in a range of approximately 40 angstroms to approximately 80 angstroms. However, other values and ranges are within the scope of the present disclosure.

As further shown in FIG. 4I, because of different segments of the base layer 206k of the bottom electrode structure 206 having different thicknesses (as described in connection with Fig. 4E), the bottom surfaces of different subsets of approximately U-shaped cross-sectional segments 208a-208i may be located at different vertical (z-direction) positions (e.g., different depths, different heights) in the recess 402. For example, a first subset of approximately U-shaped cross-sectional segments 208a-208i (e.g., approximately U-shaped cross-sectional segments 208a, 208c, 208e, 208g, and 208i) may be located above segments of the base layer 206k that have a lesser thickness (e.g., dimension D11 in FIG. 4E) than a second subset of approximately U-shaped cross-sectional segments 208a-208i (e.g., approximately U-shaped cross-sectional segments 208b, 208e, 208f, and 208h-located above segments of the base layer 206k that have a greater thickness corresponding to dimension D12 in FIG. 4E). Accordingly, the bottom surfaces of the first subset of approximately U-shaped cross-sectional segments 208a-208i (e.g., approximately U-shaped cross-sectional segments 208a, 208c, 208e, 208g, and 208i) may be located at lower vertical (z-direction) positions in the recesses 402 than the bottom surfaces of the second subset of approximately U-shaped cross-sectional segments 208a-208i (e.g., approximately U-shaped cross-sectional segments 208b, 208e, 208f, and 208h).

As shown in FIG. 4J, the top electrode structure 210 may be deposited on the insulator layer 208. Thus, the electrode plugs 210a-210i are respectively formed on the insulator layer 208 in the recesses 416a-416i. The base layer 210j of the top electrode structure 210 is formed above the recesses 416a-416i and connects the electrode plugs 210a-210i together. Portions of the base layer 210j of the top electrode structure 210 may also extend along the top surface of the ILD layer 132. In some implementations, a deposition tool is used to deposit the top electrode structure 210 using a CVD technique, ALD technique, and/or another suitable deposition technique.

The top electrode structure 210 may be deposited to a thickness (dimension D16) that is included in a range of approximately 200 angstroms to approximately 400 angstroms. However, other values and ranges are within the scope of the present disclosure. The top electrode structure 210 may be deposited to a sufficient thickness to fill in the recesses 416a-416i and form the base layer 210j above the recesses 416a-416i.

As further shown in FIG. 4J, because of different segments of the base layer 206k of the bottom electrode structure 206 having different thicknesses (as described in connection with FIG. 4E), the bottom surfaces of different subsets of electrode plugs 210a-210i may be located at different vertical (z-direction) positions (e.g., different depths, different heights) in the main trench structure 202a of the capacitor structure 160. For example, a first subset of electrode plugs 210a-210i (e.g., electrode plugs 210a, 210c, 210e, 210g, and 210i) may be located above segments of the base layer 206k that have a lesser thickness (e.g., dimension D11 in FIG. 4E) than a second subset of electrode plugs 210a-210i (e.g., electrode plugs 210b, 210d, 210f, and 210h-located above segments of the base layer 206k that have a greater thickness corresponding to dimension D12 in FIG. 4E). Accordingly, the bottom surfaces of the first subset of electrode plugs 210a-210i (e.g., electrode plugs 210a, 210c, 210e, 210g, and 210i) may be located at lower vertical (z-direction) positions in the main trench structure 202a than the bottom surfaces of the second subset of electrode plugs 210a-210i (e.g., electrode plugs 210b, 210d, 210f, and 210h).

As shown in FIG. 4K, the capping layers 212 and 214 may be formed above the main trench structure 202a of the capacitor structure 160. For example, the capping layers 212 and 214 may be formed over the base layer 210j of the top electrode structure 210 and may extend along the top surface of the ILD layer 132. A deposition tool may be used to deposit the capping layers 212 and 214 using a PVD technique, an ALD technique, a CVD technique, an oxidation technique, and/or another suitable deposition technique. In some implementations, a planarization tool may be used to perform a planarization operation (e.g., a CMP operation) to planarize the capping layers 212 and/or 214 after the capping layers 212 and/or 214 are deposited.

An etch operation may be performed to define the upper extension region 202b of the capacitor structure 160. An etch tool may be used to etch the capping layers 212 and 214, and the capping layers 212 and 214 may be used as a mask for etching the base layer 210j of the top electrode structure 210. In some implementations, the etch operation(s) may include a dry etch operation (e.g., a plasma-based etch operation, a gas-based etch operation), a wet chemical etch operation, and/or another type of etch operation.

As further shown in FIG. 4K, the sidewall spacers 216 and 218 are formed on the ends of the capping layers 212 and 214, on the ends of the base layer 210j of the top electrode structure 210. A deposition tool may be used to deposit the sidewall spacers 216 and 218 using a PVD technique, an ALD technique, a CVD technique, an oxidation technique, and/or another suitable deposition technique. The sidewall spacers 216 and 218 may be deposited in one or more deposition operations.

Another etch operation may be performed to trim portions of the liner 204, portions of the bottom electrode structure 206, and/or portions of the insulator layer 208 in the upper extension region 202b of the capacitor structure 160. The capping layers 212, 214 and the sidewall spacers 216, 218 may be used as a self-aligned mask to etch the portions of the liner 204, the portions of the bottom electrode structure 206, and/or the portions of the insulator layer 208 in the upper extension region 202b of the capacitor structure 160. In some implementations, the etch operation includes a dry etch operation (e.g., a plasma-based etch operation, a gas-based etch operation), a wet chemical etch operation, and/or another type of etch operation.

As shown in FIG. 4L, the additional material of the ILD layer 132 and the top via 142 may be formed. To form the top via 142, a recess may be formed through the ILD layer 132 and through the capping layers 212 and 214 to the base layer 210j of the top electrode structure 210. In some implementations, a pattern in a photoresist layer is used to etch the ILD layer 132 and through the capping layers 212 and 214 to form the recess. In these implementations, a deposition tool may be used to form the photoresist layer on the ILD layer 132 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the ILD layer 132 and through the capping layers 212 and 214 based on the pattern to form the recess. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess based on a pattern.

A deposition tool may be used to deposit the top via 142 using a CVD technique, a PVD technique, an ALD technique, an electroplating technique, and/or another suitable deposition technique. The top via 142 may be deposited in one or more deposition operations. In some implementations, a seed layer is first deposited in the recess, and the top via 142 is deposited on the seed layer. In some implementations, one or more liners are deposited in the recess, and the top via 142 is deposited on the liner(s). The liner(s) may include a barrier liner, an adhesion liner, and/or another type of liner. Examples of liner materials include tantalum nitride (TaN) and/or titanium nitride (TiN), among other examples. In some implementations, a planarization tool is used to perform a planarization operation (e.g., a CMP operation) to planarize the top via 142 after the top via 142 is deposited.

As indicated above, FIGS. 4A-4L are provided as an example. Other examples may differ from what is described with regard to FIGS. 4A-4L.

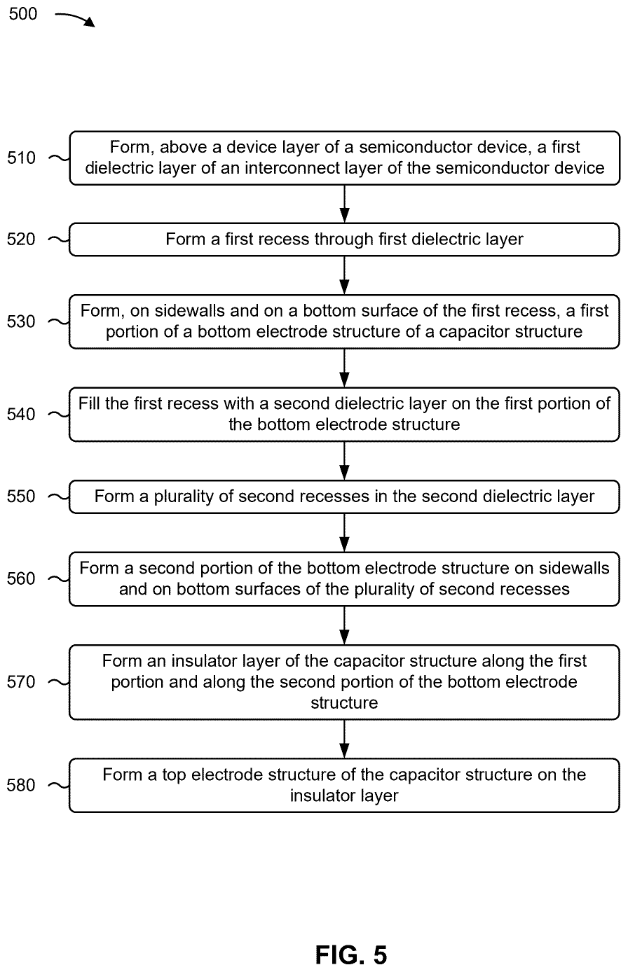

FIG. 5 is a flowchart of an example process 500 associated with forming a capacitor structure in a semiconductor device described herein. In some implementations, one or more process blocks of FIG. 5 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 5, process 500 may include forming, above a device layer of a semiconductor device, a first dielectric layer of an interconnect layer of the semiconductor device (block 510). For example, one or more semiconductor processing tools may be used to form, above a device layer (e.g., device layer 104, a substrate layer 110 of the device layer 104) of a semiconductor device (e.g., a semiconductor device 102), a first dielectric layer (e.g., an ILD layer 116, an ESL 118, an ESL 122, an ILD layer 124, an ESL 126, an ILD layer 128, an ESL 130, an ILD layer 132) of an interconnect layer (e.g., an interconnect layer 106) of the semiconductor device, as described herein.

As further shown in FIG. 5, process 500 may include forming a first recess through the first dielectric layer (block 520). For example, one or more semiconductor processing tools may be used to form a first recess (e.g., a recess 402 through the first dielectric layer, as described herein. In some implementations, a conductive structure (e.g., a conductive structure 120) in the interconnect layer is exposed through the first recess.

As further shown in FIG. 5, process 500 may include forming, on sidewalls and on a bottom surface of the first recess, a first portion of a bottom electrode structure of a capacitor structure (block 530). For example, one or more semiconductor processing tools may be used to form, on sidewalls and on a bottom surface of the first recess, a first portion (e.g., electrode walls 206a and 206j, a base layer 206k) of a bottom electrode structure (e.g., a bottom electrode structure 206) of a capacitor structure (e.g., a capacitor structure 160), as described herein.

As further shown in FIG. 5, process 500 may include filling the first recess with a second dielectric layer on the first portion of the bottom electrode structure (block 540). For example, one or more semiconductor processing tools may be used to fill the first recess with a second dielectric layer (e.g., a dielectric plug 404) on the first portion of the bottom electrode structure, as described herein.

As further shown in FIG. 5, process 500 may include forming a plurality of second recesses in the second dielectric layer (block 550). For example, one or more semiconductor processing tools may be used to form a plurality of second recesses (e.g., recesses 406a-404d) in the second dielectric layer, as described herein.

As further shown in FIG. 5, process 500 may include forming a second portion of the bottom electrode structure on sidewalls and on bottom surfaces of the plurality of second recesses (block 560). For example, one or more semiconductor processing tools may be used to form a second portion (e.g., electrode walls 206b-206i, additional portions of the base layer 206k) of the bottom electrode structure on sidewalls and on bottom surfaces of the plurality of second recesses, as described herein.

As further shown in FIG. 5, process 500 may include forming an insulator layer of the capacitor structure along the first portion and along the second portion of the bottom electrode structure (block 570). For example, one or more semiconductor processing tools may be used to form an insulator layer (e.g., an insulator layer 208) of the capacitor structure along the first portion and along the second portion of the bottom electrode structure, as described herein.

As further shown in FIG. 5, process 500 may include forming a top electrode structure of the capacitor structure on the insulator layer (block 580). For example, one or more semiconductor processing tools may be used to form a top electrode structure (e.g., a top electrode structure 210) of the capacitor structure on the insulator layer, as described herein.

Process 500 may include additional implementations, such as any single implementation or any combination of implementations described below and/or in connection with one or more other processes described elsewhere herein.

In a first implementation, forming the first portion of the bottom electrode structure includes forming a base layer (e.g., a base layer 206k) of the bottom electrode structure on the bottom surface of the first recess, and forming outer vertical walls (e.g., electrode walls 206a and 206j) of the bottom electrode structure on the sidewalls of the first recess.

In a second implementation, alone or in combination with the first implementation, forming the second portion of the bottom electrode structure includes forming inner vertical walls (e.g., electrode walls 206b-206i) of the bottom electrode structure on the sidewalls of the plurality of second recesses.

In a third implementation, alone or in combination with one or more of the first and second implementations, process 500 includes removing remaining portions of the second dielectric layer after forming the second portion of the bottom electrode structure, where forming the top electrode structure includes forming elongated plugs (e.g., electrode plugs 210a-210i) of the top electrode structure in between the outer vertical walls and the inner vertical walls of the bottom electrode structure.

In a fourth implementation, alone or in combination with one or more of the first through third implementations, forming the second portion of the bottom electrode structure includes forming the second portion of the bottom electrode structure on tops of remaining portions of the second dielectric layer, and etching the second portion of the bottom electrode structure on the tops of remaining portions of the second dielectric layer such that the second portion of the bottom electrode structure remain on sidewalls and 02on bottom surfaces of the plurality of second recesses.

In a fifth implementation, alone or in combination with one or more of the first through fourth implementations, process 500 includes filling the plurality of second recesses with patterning plugs (e.g., patterning plugs 414a-414d), where etching the second portion of the bottom electrode structure on the tops of remaining portions of the second dielectric layer includes etching the second portion of the bottom electrode structure on the tops of remaining portions of the second dielectric layer after filling the plurality of second recesses with the patterning plugs.

In a sixth implementation, alone or in combination with one or more of the first through fifth implementations, process 500 includes removing the remaining portions of the second dielectric layer and the patterning plugs after etching the second portion of the bottom electrode structure on the tops of remaining portions of the second dielectric layer.

In a seventh implementation, alone or in combination with one or more of the first through sixth implementations, removing the patterning plugs includes performing a photoresist ashing operation to remove the patterning plugs, and removing the remaining portions of the second dielectric layer includes performing an etch operation to remove the removing the remaining portions of the second dielectric layer.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

In this way, a capacitor structure (e.g., a trench capacitor structure) is formed in an interconnect layer of a semiconductor device. Instead of etching the dielectric layers of the interconnect layer to form the trenches (e.g., the deep trenches) for the capacitor structure, a wide main trench (e.g., having a relatively low aspect ratio) is formed in the dielectric layers of the interconnect layer. The main trench is filled with a dielectric plug, and the dielectric plug is patterned and used to form a plurality of columns of a bottom electrode structure of the capacitor structure. The columns of the bottom electrode structure define a plurality of secondary trenches (e.g., that have a relatively high aspect ratio) in the main trench that are then lined with an insulator layer of the capacitor structure and filled in with a plurality of columns of a top electrode structure of the capacitor structure.

As described in greater detail above, some implementations described herein provide a semiconductor structure. The semiconductor structure includes a bottom electrode structure comprising a plurality of electrode walls vertically extending from a first base layer of the bottom electrode structure. The semiconductor structure includes an insulator layer on sidewalls of the plurality of electrode walls and on the first base layer. The semiconductor structure includes a top electrode structure comprising a plurality of electrode plugs vertically extending from a second base layer of the top electrode structure. The semiconductor device includes an interconnection structure with a trench region, where the first base layer extends from one end of the trench region to an opposing end of the trench region along a horizontal plane and is overlapped by the second plurality of columns.

As described in greater detail above, some implementations described herein provide a method. The method includes forming, above a device layer of a semiconductor device, a first dielectric layer of an interconnect layer of the semiconductor device. The method includes forming a first recess through at least a subset of the first dielectric layer. The method includes forming, on sidewalls on a bottom surface of the first recess, a first portion of a bottom electrode structure of a capacitor structure. The method includes filling the first recess with a second dielectric layer on the first portion of the bottom electrode structure. The method includes forming a plurality of second recesses in the second dielectric layer. The method includes forming a second portion of the bottom electrode structure on sidewalls and on bottom surfaces of the plurality of second recesses. The method includes forming an insulator layer of the capacitor structure along the first portion and along the second portion of the bottom electrode structure. The method includes forming a top electrode structure of the capacitor structure on the insulator layer.

As described in greater detail above, some implementations described herein provide a semiconductor structure. The semiconductor structure includes a bottom electrode structure that includes a first plurality of columns vertically extending from a first base layer of the bottom electrode structure. First segments of the first base layer each have a first thickness. Second segments of the first base layer each have a second thickness that is greater than the first thickness. The semiconductor structure includes an insulator layer on sidewalls of the plurality of columns and on the base layer. The semiconductor structure includes a top electrode structure that includes a second plurality of columns vertically extending from a second base layer of the top electrode structure.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a bottom electrode structure comprising a first plurality of columns vertically extending from a first base layer of the bottom electrode structure;
an insulator layer on sidewalls of the first plurality of columns and on the first base layer;
a top electrode structure comprising a second plurality of columns vertically extending from a second base layer of the top electrode structure; and
an interconnection structure with a trench region,
wherein the first base layer extends from one end of the trench region to an opposing end of the trench region along a horizontal plane and is overlapped by the second plurality of columns.

2. The semiconductor structure of claim 1, wherein the first plurality of columns vertically extend above the first base layer; and
wherein the second plurality of columns vertically extend below the second base layer.

3. The semiconductor structure of claim 1, wherein the first plurality of columns and the second plurality of columns are arranged in a horizontally alternating manner in the semiconductor structure.

4. The semiconductor structure of claim 1, wherein the insulator layer comprises a plurality of approximately U-shaped cross-sectional segments; and
wherein adjacent approximately U-shaped cross-sectional segments, of the plurality of approximately U-shaped cross-sectional segments, are connected together at tops of the adjacent approximately U-shaped cross-sectional segments.

5. The semiconductor structure of claim 4, wherein the plurality of approximately U-shaped cross-sectional segments and the first plurality of columns are arranged in a horizontally alternating manner in the semiconductor structure.

6. The semiconductor structure of claim 4, wherein the second plurality of columns extend into the plurality of approximately U-shaped cross-sectional segments.

7. The semiconductor structure of claim 4, further comprising:
a liner between the bottom electrode structure and an underlying capacitor through-via structure,
wherein the liner extends under the plurality of approximately U-shaped cross-sectional segments, and
wherein the plurality of approximately U-shaped cross-sectional segments, the first plurality of columns, and the second plurality of columns are arranged in a horizontally alternating manner in the semiconductor structure without the liner intervening between the approximately U-shaped cross-sectional segments, the first plurality of columns, and the second plurality of columns.

8. A method, comprising:
forming, above a device layer of a semiconductor device, a first dielectric layer of an interconnect layer of the semiconductor device;
forming a first recess through the first dielectric layer;
forming, on sidewalls and on a bottom surface of the first recess, a first portion of a bottom electrode structure of a capacitor structure;
filling the first recess with a second dielectric layer on the first portion of the bottom electrode structure;
forming a plurality of second recesses in the second dielectric layer;
forming a second portion of the bottom electrode structure on sidewalls and on bottom surfaces of the plurality of second recesses;
forming an insulator layer of the capacitor structure along the first portion and along the second portion of the bottom electrode structure; and
forming a top electrode structure of the capacitor structure on the insulator layer.

9. The method of claim 8, wherein forming the first portion of the bottom electrode structure comprises:
forming a base layer of the bottom electrode structure on the bottom surface of the first recess; and
forming outer vertical walls of the bottom electrode structure on the sidewalls of the first recess.

10. The method of claim 9, wherein forming the second portion of the bottom electrode structure comprises:
forming inner vertical walls of the bottom electrode structure on the sidewalls of the plurality of second recesses.

11. The method of claim 10, further comprising:
removing remaining portions of the second dielectric layer after forming the second portion of the bottom electrode structure,
wherein forming the top electrode structure comprises:
forming elongated plugs of the top electrode structure in between the outer vertical walls and the inner vertical walls of the bottom electrode structure.

12. The method of claim 8, wherein forming the second portion of the bottom electrode structure comprises:
forming the second portion of the bottom electrode structure on tops of remaining portions of the second dielectric layer; and
etching the second portion of the bottom electrode structure on the tops of remaining portions of the second dielectric layer such that the second portion of the bottom electrode structure remain on sidewalls and on bottom surfaces of the plurality of second recesses.

13. The method of claim 12, further comprising:
filling the plurality of second recesses with patterning plugs,
wherein etching the second portion of the bottom electrode structure on the tops of remaining portions of the second dielectric layer comprises:
etching the second portion of the bottom electrode structure on the tops of remaining portions of the second dielectric layer after filling the plurality of second recesses with the patterning plugs.

14. The method of claim 13, further comprising:
removing the remaining portions of the second dielectric layer and the patterning plugs after etching the second portion of the bottom electrode structure on the tops of remaining portions of the second dielectric layer.

15. The method of claim 14, wherein removing the patterning plugs comprises:
performing a photoresist ashing operation to remove the patterning plugs; and
wherein removing the remaining portions of the second dielectric layer comprises:
performing an etch operation to remove the removing the remaining portions of the second dielectric layer.

16. A semiconductor structure, comprising:
a bottom electrode structure comprising a plurality of electrode walls vertically extending from a first base layer of the bottom electrode structure,
wherein first segments of the first base layer each have a first thickness, and
wherein second segments of the first base layer each have a second thickness that is greater than the first thickness;
an insulator layer on sidewalls of the plurality of electrode walls and on the first base layer; and
a top electrode structure comprising a plurality of electrode plugs vertically extending from a second base layer of the top electrode structure.

17. The semiconductor structure of claim 16, wherein first bottoms of a first subset of the plurality of electrode plugs located above the first segments of the first base layer are located at a lower vertical position than second bottoms of a second subset of the plurality of electrode plugs located above the second segments of the first base layer.

18. The semiconductor structure of claim 16, wherein the insulator layer comprises a plurality of approximately U-shaped cross-sectional segments; and
wherein adjacent approximately U-shaped cross-sectional segments, of the plurality of approximately U-shaped cross-sectional segments, are connected together at tops of the adjacent approximately U-shaped cross-sectional segments.

19. The semiconductor structure of claim 18, wherein first bottoms of a first subset of the plurality of approximately U-shaped cross-sectional segments located above the first segments of the first base layer are located at a lower vertical position than second bottoms of a second subset of the plurality of approximately U-shaped cross-sectional segments located above the second segments of the first base layer.

20. The semiconductor structure of claim 18, wherein the plurality of electrode plugs extend into the plurality of approximately U-shaped cross-sectional segments.
